(19) United States
(12) Patent Application Publication
(10) Pub. No.: US 2025/0079427 A1
(43) Pub. Date: Mar. 6, 2025

(54) METHOD FOR FABRICATING FAN-OUT PACKAGE

(71) Applicant: Yibu Semiconductor Co., Ltd., Shanghai (CN)

(72) Inventor: Wenqi Li, Shanghai (CN)

(73) Assignee: Yibu Semiconductor Co., Ltd., Shanghai (CN)

(21) Appl. No.: 18/822,052

(22) Filed: Aug. 30, 2024

(30) Foreign Application Priority Data
Aug. 30, 2023 (CN) 202311110768.X
Aug. 30, 2023 (CN) 202311115225.7
Aug. 30, 2023 (CN) 202311115241.6

(51) Int. Cl. H01L 25/00; H01L 21/56; H01L 23/00

(52) U.S. Cl. CPC H01L 25/50; H01L 21/561; H01L 24/19; H01L 24/97; H01L 2224/19; H01L 2224/95001

(57) ABSTRACT

The present disclosure relates to the fabrication method for fan-out packages, in which packaging material layers (including a molding layer and/or a redistribution layer) are formed on both the upper and lower surfaces of a supporting carrier using a dual-sided carrier packaging method. The stress generated by the packaging material layer(s) on the upper surface is opposite to, while similar to or about equal in magnitude as, the stress generated by the packaging material layer(s) on the lower surface. Thus, the stress generated by forming the packaging material layers on two opposite sides of the carrier can offset each other, reducing or eliminating the degree of warpage, resulting in improved packaging efficiency and yield.

### CROSS REFERENCE TO RELATED APPLICATION

The present application claims the benefit of priority under the Paris Convention to Chinese Patent Application No. 202311115225.7, filed on Aug. 30, 2023, Chinese Patent Application No. 202311110768.X, filed on Aug. 30, 2023, and Chinese Patent Application No. 202311115241.6, filed on Aug. 30, 2023, each of which is incorporated herein by reference in its entirety.

### TECHNICAL FIELD

The present disclosure relates to the field of semiconductor technology, and in particular to a method for fabricating fan-out package.

### BACKGROUND

With the rapid development of the semiconductor industry, chip sizes are getting smaller and smaller, while the number and density of signal connections on a chip keep increasing. Conventional packages cannot meet the requirements of the ever-decreasing chip sizes and the ever-increasing number of signal connections. Wafer Level fan-out Packaging (fan-out Wafer Level Package, FOWLP) technology is a chip embedded packaging method for Wafer Level assembly processes, which has been widely applied to the semiconductor assembly industry, as it can bring a lot of advantages for the package with large number of connections and provide flexibility for both design and production.

In the Wafer Level fan-out package process, due to mismatch of Thermal Expansion Coefficients (Coefficient of Thermal Expansion, CTE) between different package materials, wafer warpage often occurs, which adversely impacts packaging efficiency and yield.

### SUMMARY

To solving the technical problems, the present disclosure provides a method to fabricate fan-out package, which reduces package warpage through a dual side assembly process, thereby reducing the effects caused by warpage.

The present disclosure provides a fabrication method for fan-out package. The method comprises forming packaging layers on opposite sides of a carrier board, the packaging layers including one or more first packaging layers on a first side of the carrier board and one or more second package layers on a second side of the carrier board. The second side is opposite to the first side, the one or more first packaging layers include a first molded package layer, the one or more second packaging layers include a second molded package layer, and at least the first molded package layer embeds one or more semiconductor devices.

In some embodiments, forming packaging layers on opposite sides of a carrier board includes the following steps and processes:
Providing a supporting carrier; the supporting carrier has a first surface and a second surface, which are on opposite sides of the carrier;
Forming a first bonding layer on the first surface and forming a second bonding layer on the second surface;
Providing semiconductor devices, and attaching the passive surfaces of the semiconductor devices onto the first bonding layer facing away from the supporting carrier and/or onto the second bonding layer facing away from the supporting carrier;
Forming a plastic sealing or molding layer; the molding layer embeds the semiconductor devices while exposing the active surfaces of the semiconductor devices, and the molding layer also covers a surface of the first bonding layer facing away from the supporting carrier, and a surface of the second bonding layer facing away from the supporting carrier, that are not covered by the semiconductor device; and
Forming a redistribution layer on the surface one one side of the molding layer, which is away from the first bonding layer, and the surface on one side of the molding layer, which is away from the second bonding layer; the redistribution layers are electrically connected to the active surfaces of the semiconductor devices.

In some embodiments, forming the first bonding layer on the first surface and forming the second bonding layer on the second surface includes:
Forming the first bonding layer and the second bonding layer by a taping or lamination process; or
Forming the first bonding layer and the second bonding layer by a coating process;
And curing the first bonding layer and the second bonding layer.

In some embodiments, forming the molding layer includes:
Forming the molding layer on a surface of the first bonding layer facing away from the supporting carrier, and a surface of the second bonding layer facing away from the supporting carrier; wherein, the molding layer embeds the semiconductor device, and the molding layer also covers a surface of the first bonding layer facing away from the supporting carrier and a surface of the second bonding layer facing away from the supporting carrier. The surfaces of the bonding layers are not covered by the semiconductor device;
And polishing back the molding layer to expose the active surfaces of the semiconductor devices.

In some embodiments, forming the molding layer includes:
Forming the molding layer by using a compression molding or a transfer molding process.

In some embodiments, attaching the mentioned passive surface of the semiconductor device onto the side surface of the first bonding layer facing away from the supporting carrier and/or onto the side surface of the second bonding layer facing away from the supporting carrier includes:
Attaching a passive surface of the semiconductor device onto the side surface of the first bonding layer facing away from the supporting carrier and onto the side surface of the second bonding layer facing away from the supporting carrier;
In some embodiments, along the thickness direction of the molding layer, the projection of the semiconductor device attached to the first bonding layer overlaps with the projection of the semiconductor device attached to the second bonding layer.

In some embodiments, the mentioned redistribution layer includes of at least one metal layer and at least one insulator layer, wherein the metal layer corresponds to the insulator layer one by one; the redistribution layer is formed on the side surface of the molding layer facing away from the first bonding layer and the side surface of the molding layer facing away from the second bonding layer, includes:
On the side surface of the molding layer facing away from the first bonding layer, and on the side surface of the molding layer facing away from the second bonding layer, are sequentially and alternately formed one metal layer and one isolating layer, until the side surface of the molding layer facing away from the first bonding layer is formed into all metal layers and all isolating layers of the redistribution layer, and the side surface of the molding layer facing away from the second bonding layer is formed into all metal layers and all isolating layers of the redistribution layer.

In some embodiments, after the redistribution layers are formed on both the side surface of the molding layer facing away from the first bonding layer and the side surface of the molding layer facing away from the second bonding layer, the fabrication method further includes:
Forming a connection structure on the side surface of the redistribution layer, which is away from the semiconductor device; the connection structure is electrically connected to the redistribution layer and is used for connecting an external device.

In some embodiments, the method for removing the supporting carrier includes one of thermal debonding, laser debonding and mechanical debonding.

In some embodiments, after removing the supporting carrier, the fabrication method of fan-out packages further includes:

dicing (or segmenting) at least the first packaging layers to obtain fan-out packages; wherein the saw process includes at least one of dicing saw, laser grooving, and plasma cutting.

In some embodiments, forming packaging layers on opposite sides of a carrier board includes the following steps and processes:
Providing a supporting carrier; the supporting carrier has a first surface and a second surface which are on opposite sides of the carrier;
Forming a first bonding layer on the first surface and forming a second bonding layer on the second surface;
Providing semiconductor devices and attaching the active surfaces of the semiconductor devices to a side surface of the first bonding layer facing away from the supporting carrier;
Forming a molding layer; the molding layer embeds the semiconductor devices and the surface of the first bonding layer facing away from the supporting carrier that is not covered by the semiconductor devices and the second bonding layer. The interconnection layer is on a side surface facing away from the supporting carrier.

In some embodiments, forming a first bonding layer on the first surface and forming a second bonding layer on the second surface includes:
Forming the first bonding layer and the second bonding layer by a taping or lamination process; or, forming the first bonding layer and the second bonding layer by a coating process; and
curing the first bonding layer and the second bonding layer by a coating process.

In some embodiments, after the attaching the active surface of the semiconductor devices to the surface of the side of the first bonding layer facing away from the supporting carrier, the fabrication method further includes:

Attaching a stress balancing device to the surface of the side of the second bonding layer away from the supporting carrier; and the projection of the semiconductor devices are overlapped with the projection of the stresses balance device along the thickness direction of the supporting carrier.

In some embodiments, forming the molding layer includes:

Forming the molding layer by using a compression molding or a transfer molding process.

In some embodiments, after forming of the molding layer, the fabrication method further includes:

Forming a groove on the surface of the side of the molding layer, which is away from the first bonding layer; the grooves are used for releasing stresses.

In some embodiments, forming a groove on a surface of the molding layer facing away from the first bonding layer includes:

And forming the groove on the surface of the side of the molding layer, which is away from the first bonding layer, between two adjacent semiconductor devices.

In some embodiments, the forming the groove on a surface of a side, facing away from the first bonding layer, of the molding layer between two adjacent semiconductor devices includes:

And along the thickness direction of the molding layer, the depth of the groove is smaller than or equal to ½ of the thickness of the molding layer.

In some embodiments, after forming of the molding layer, the method for removing the supporting carrier includes one of thermal debonding, laser debonding and mechanical debonding to expose the active surface of the semiconductor devices.

In some embodiments, the fabrication method further comprises:
Forming an interconnection structure on the surface of the side of the molding layer, which is exposed out of the active surface; the interconnection structure is electrically connected to the active surface and is used for connecting an external device; and
dicing (or segmenting) at least the first packaging layers to obtain fan-out packages; wherein the saw process includes at least one of dicing saw, dicing blades, laser grooving, and plasma cutting.

In some embodiments, forming packaging layers on opposite sides of a carrier board includes the following steps and processes:
Providing a supporting carrier; the supporting carrier has a first surface and a second surface which are on opposite sides of the carrier;
Forming a first bonding layer on the first surface and forming a second bonding layer on the second surface;
Forming a first redistribution layer on one side of the first bonding layer, which is away from the supporting carrier, and forming a second redistribution layer on one side of the second bonding layer, which is away from the supporting carrier;
Providing semiconductor devices and attaching an active face of the semiconductor devices to the first and/or second redistribution layers;
Forming a molding layer; the molding layer embeds the semiconductor devices and also covers the first redistribution layer facing away from the one side surface of the first bonding layer, and covers the second redistribution layer facing away from the one side surface of the second bonding layer, which is not covered by the semiconductor devices.

In some embodiments, a first redistribution layer includes at least one metal layer and at least one insulator layer; a second redistribution layer comprises at least one metal layer and at least one insulator layer; the first redistribution layer is formed on one side of the first bonding layer, which is away from the supporting carrier, and the second redistribution layer is formed on one side of the second bonding layer, which is away from the supporting carrier, and the redistribution layer comprises:
One side of the first bonding layer, which is away from the supporting carrier, and one side of the second bonding layer, which is away from the supporting carrier, alternately forming a metal layer and an insulator layer in sequence until one side of the first bonding layer, which is away from the supporting carrier; forming all metal layers and insulator layers of the first redistribution layer, and one side of the second bonding layer, which is away from the supporting carrier; forming all metal layers and insulator layers of the second redistribution layer.

In some embodiments, forming a first bonding layer on the first surface and forming a second bonding layer on the second surface includes: forming the bonding layer by adopting a taping process; or, forming the bonding layer by adopting a coating process; and further includes curing the bonding layer formed by the coating process.

In some embodiments, attaching an active face of the semiconductor devices to the first redistribution layer and/or the second redistribution layer includes:
Attaching an active face of the semiconductor devices to a side surface of the first redistribution layer facing away from the first bonding layer and a side surface of the second redistribution layer facing away from the second bonding layer;
In some embodiments, along the thickness direction of the support carrier, the projection of the semiconductor devices attached to the first redistribution layer overlaps with the projection of the semiconductor devices attached to the second redistribution layer.

In some embodiments, attaching an active face of the semiconductor devices to the first redistribution layer and/or the second redistribution layer includes:
Attaching an active surface of the semiconductor devices to a surface of the first redistribution layer facing away from the first bonding layer;
Attaching a stress balancing device to a surface of the second redistribution layer facing away from the second bonding layer;
In some embodiments, the projection of the semiconductor devices is overlapped with the projection of the stress balance device along the thickness direction of the supporting carrier.

In some embodiments, forming the molding layer includes:
Forming a molding layer by adopting a compression molding or transfer molding process.

In some embodiments, the fabrication method further comprises:
Forming a groove on the surface of one side of the molding layer, which faces away from the supporting carrier; the grooves are used for releasing stress.

In some embodiments, forming a groove on a surface of the molding layer facing away from the supporting carrier includes:
Forming a groove on the surface of one side of the molding layer, which faces away from the support carrier, between two adjacent semiconductor devices.

In some embodiments, forming a groove on a surface of a side, facing away from the supporting carrier, of the molding layer between two adjacent semiconductor devices includes:

Along the thickness direction of the molding layer, the depth of the groove is smaller than or equal to ½ of the thickness of the molding layer.

In some embodiments, after forming of the molding layer, the fabrication method further includes:

Removing the supporting carrier and the bonding layer by adopting one of thermal debonding, laser debonding and mechanical debonding.

Compared with the current technology, the technical scheme provided by the disclosure has the following advantages.

In some embodiments, the fabrication method of fan-out packages provided by the disclosure comprises the following steps: providing a supporting carrier; the supporting carrier comprises a first surface and a second surface which are at opposite sides of the supporting carrier; forming a first bonding layer on the first surface and forming a second bonding layer on the second surface; providing a semiconductor device, and attaching a passive surface of the semiconductor device onto a side surface of the first bonding layer facing away from the supporting carrier and/or a side surface of the second bonding layer facing away from the supporting carrier; forming a molding layer; the molding layer wraps the semiconductor device and exposes the active surface of the semiconductor device, the molding layer also covers the surface of the first bonding layer facing away from the supporting carrier and the surface of the second bonding layer facing away from the supporting carrier which are not covered by the semiconductor device; a redistribution layer is formed on both the side surface of the molding layer facing away from the first bonding layer and the side surface of the molding layer facing away from the second bonding layer; the redistribution layer is electrically connected to the active surface of the semiconductor device. Therefore, the fabrication method for fan-out packages, in which the same packaging material layer (including a bonding layer, a molding layer and a redistribution layer) is formed on both the upper and lower sides of the supporting carrier by using a Dual-sided Carrier packaging method, and the stress generated by the packaging material layer on the upper surface is opposite to the stress generated by the packaging material layer on the lower surface, and the two stresses are similar or equal in size, and can offset each other, reducing the degree of warpage or even eliminating warpage, which is beneficial to improve packaging efficiency and yield.

In some embodiments, the fabrication method of fan-out packages provided by the disclosure comprises the following steps: providing a supporting carrier; the supporting carrier comprises a first surface and a second surface which are at opposite sides of the supporting carrier; forming a first bonding layer on the first surface and forming a second bonding layer on the second surface; providing the semiconductor devices, and attaching a passive surface of the semiconductor devices onto a side surface of the first bonding layer facing away from the supporting carrier; forming a molding layer; the molding layer covers the semiconductor devices and the surface of the first bonding layer facing away from the supporting carrier that is not covered by the semiconductor devices and the second bonding layer facing away from the supporting carrier. Therefore, the fabrication method for fan-out packages, in which the same packaging material layer is formed on both the upper and lower sides of the supporting carrier by using a Dual-sided Carrier packaging method, and the stresses generated by the packaging material layer on the upper surface are opposite to the stresses generated by the packaging material layer on the lower surface, and the two stresses are similar or equal in size, and can offset each other, reducing the warpage degree or even eliminating warpage, which is beneficial to improve packaging efficiency and yield.

In some embodiments, the fabrication method of the fan-out package provided by the disclosure comprises the following steps: providing a supporting carrier; the supporting carrier comprises a first surface and a second surface which are oppositely arranged; forming a first bonding layer on the first surface and forming a second bonding layer on the second surface; forming a first redistribution layer on one side of the first bonding layer, which is away from the supporting carrier, and forming a second redistribution layer on one side of the second bonding layer, which is away from the supporting carrier; providing a semiconductor devices and attaching an active face of the semiconductor devices to the first and/or second redistribution layers; forming a molding layer; the molding layer embeds the semiconductor devices and also covers the surface, which is not covered by the semiconductor devices, of the side surface of the first redistribution layer, which is away from the first bonding layer, and the side surface of the second redistribution layer, which is away from the second bonding layer. Therefore, the fabrication method for fan-out packages, in which the same packaging material layer (including a bonding layer, a redistribution layer and a molding layer) is formed on both the upper and lower sides of the supporting carrier by using a Dual-sided Carrier packaging method, and the stress generated by the packaging material layer on the upper surface is opposite to the stress generated by the packaging material layer on the lower surface, and the two stresses are similar or equal in size, and can offset each other, reducing the degree of warpage or even eliminating warpage, which is beneficial to improve the packaging efficiency and yield.

The fabrication method of the fan-out package provided by the disclosure comprises the following steps: providing a supporting carrier; the supporting carrier comprises a first surface and a second surface which are oppositely arranged; forming a first bonding layer on the first surface and forming a second bonding layer on the second surface; forming a first redistribution layer on one side of the first bonding layer, which is away from the supporting carrier, and forming a second redistribution layer on one side of the second bonding layer, which is away from the supporting carrier; providing a semiconductor devices and attaching an active face of the semiconductor devices to the first and/or second redistribution layers; forming a molding layer; the molding layer embeds the semiconductor devices and also covers the surface, which is not covered by the semiconductor devices, of the side surface of the first redistribution layer, which is away from the first bonding layer, and the side surface of the second redistribution layer, which is away from the second bonding layer. Therefore, the fabrication method for fan-out packages, in which the same packaging material layer (including a bonding layer, a redistribution layer and a molding layer) is formed on both the upper and lower sides of the supporting carrier by using a Dual-sided Carrier packaging method, and the stress generated by the packaging material layer on the upper surface is opposite to the stress generated by the packaging material layer on the lower surface, and the two stresses are similar or equal in size, and can offset each other, reducing the degree of warpage or even eliminating warpage, which is beneficial to improve the packaging efficiency and yield.

### BRIEF DESCRIPTION OF THE DRAWINGS

The accompanying drawings, which are incorporated in and constitute a part of this specification, illustrate embodiments includeent with the disclosure and together with the description, serve to explain the principles of the disclosure.

In order to more clearly illustrate the embodiments of the present disclosure or the technical solutions in the prior technologies, the drawings that are required for the description of the embodiments or the prior technologies will be briefly described below, and it will be obvious to those skilled in the technologies that other drawings can be obtained from these drawings without inventive efforts.

FIG. 1 is a schematic flow chart of a method for manufacturing a fan-out package according to an embodiment of the disclosure.

FIG. 2 is a schematic flow chart of a method for manufacturing a fan-out package according to an embodiment of the disclosure.

FIG. 3 is a schematic structural diagram of various steps in a fabrication method of a fan-out package according to an embodiment of the disclosure.

FIG. 4 is a schematic structural diagram of various steps in another fabrication method of a fan-out package according to an embodiment of the disclosure.

FIGS. 5 and 6 are schematic illustrations of warpage reduction provided by embodiments of the present disclosure.

FIG. 7 is a detailed flow schematic diagram of “forming a molding layer” in the fabrication method of the fan-out packages shown in FIG. 2.

FIG. 8 is a schematic flow chart of a method for manufacturing a fan-out package according to an embodiment of the disclosure.

FIG. 9 is a schematic structural diagram of each step in a fabrication method of a fan-out package according to an embodiment of the disclosure.

FIG. 10 is a schematic structural diagram of each step in another fabrication method of a fan-out package according to an embodiment of the present disclosure.

FIG. 11 is a schematic structural diagram of a fan-out package according to an embodiment of the disclosure.

FIG. 12 is a schematic structural diagram of another fan-out package according to an embodiment of the disclosure.

FIG. 13 is a schematic flow chart of a method for manufacturing a fan-out package according to an embodiment of the disclosure.

FIG. 14 is a schematic structural diagram of various steps in a fabrication method of a fan-out package according to an embodiment of the disclosure.

FIG. 15 is a schematic structural diagram of various steps in another fabrication method of a fan-out package according to an embodiment of the disclosure.

FIG. 16 is a schematic structural diagram of a fan-out package according to an embodiment of the disclosure.

FIG. 17 is a schematic structural diagram of another fan-out package according to an embodiment of the present disclosure.

FIG. 18 is a schematic structural diagram of still another fan-out package according to an embodiment of the present disclosure.

According to some embodiments, the following reference numerals are used to denote certain components/layers in the drawings:
1. support carrier (carrier board or substrate);
2. bonding layer;
3. semiconductor device;
4. molding layer;
5. redistribution layer;
6. solder balls;
7. stresses balancing devices;
11. first surface;
12. second surface;
21. first bonding layer;
22. second bonding layer;
51. irst redistribution layer;
52. second redistribution layer.

### DETAILED DESCRIPTION OF THE EMBODIMENTS

In order that more clearly understand the above-mentioned objects, features and advantages of the present disclosure, a further description of the solutions of the present disclosure will be discussed below. It should be noted that, if there is no conflict, the embodiments of the present disclosure and the features in the embodiments can be combined with each other.

In the following description, numerous specific details are set forth in order to provide a thorough understanding of the present disclosure, however, the present disclosure may also be implemented in other ways than described herein; it will be obvious that the embodiments in the description are only part of the embodiments of the present disclosure, and not all examples.

The following describes an exemplary fabrication method for manufacturing a fan-out package according to an embodiment of the present disclosure with reference to the accompanying drawings.

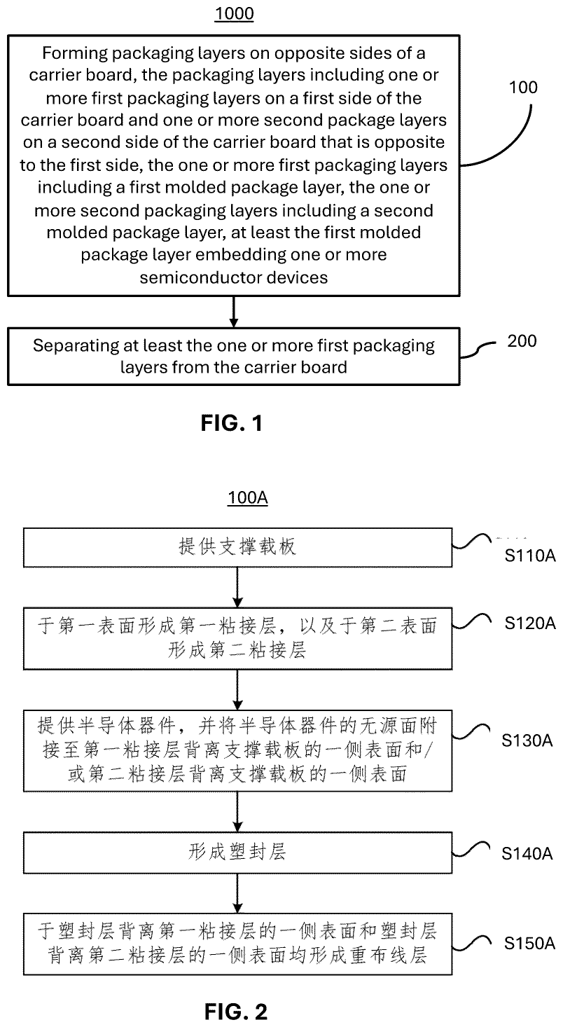

FIG. 1 is a flowchart illustrating a method 1000 for fabricating fan-out package. The method 1000 comprises process 100, in which packaging layers are formed on opposite sides of a carrier board or substrate, the packaging layers including one or more first packaging layers on a first side of the carrier board and one or more second package layers on a second side of the carrier board. The second side is opposite to the first side, the one or more first packaging layers include a first molded package layer, the one or more second packaging layers include a second molded package layer, and at least the first molded package layer embeds one or more semiconductor devices. The method further comprises a process 200, in which at least the first package layers are separated from the carrier board.

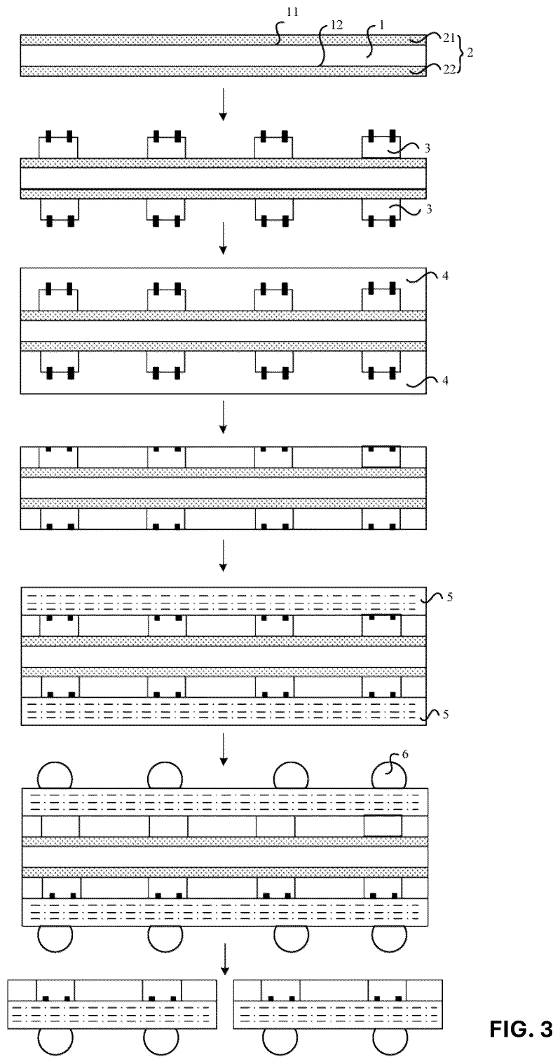

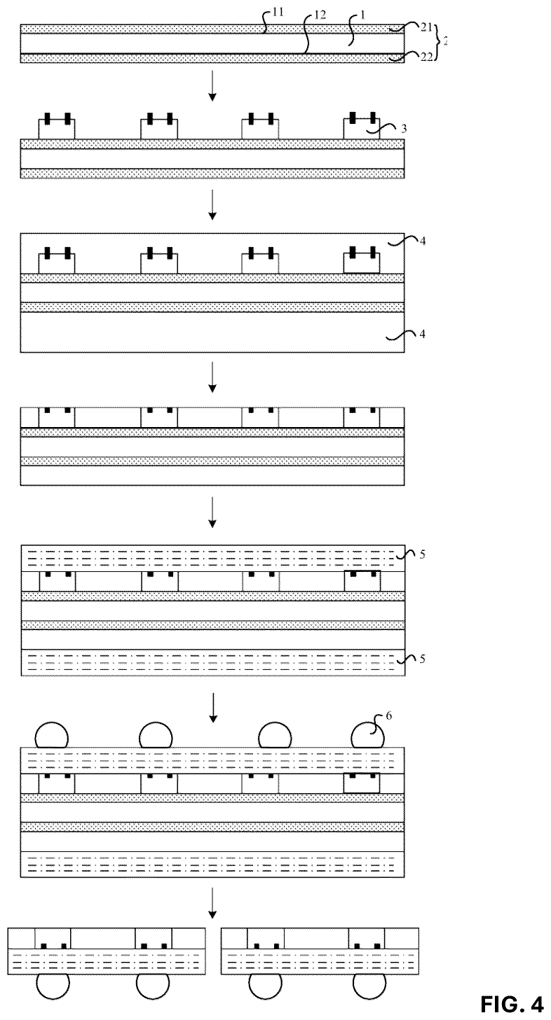

FIG. 2 is a schematic flow chart of an implementation 100A of the process 100 in the fabrication method 1000 for manufacturing a fan-out package, provided by an embodiment of the present disclosure, FIG. 3 is a schematic diagram of various steps in a fabrication method for manufacturing a fan-out package provided by an embodiment of the present disclosure, FIG. 4 is a schematic diagram of various steps in another method for manufacturing a fan-out package provided by an embodiment of the present disclosure. Referring to FIGS. 1-3, the fabrication method includes the following steps:

S110A, providing a supporting carrier.

In some embodiments, the supporting carrier 1 is used for fixing and supporting the package; the supporting carrier 1 can be selected from all types of carriers known to those skilled in the technologies, such as a glass carrier or a stainless steel carrier and so on, which is not limited herein. The supporting carrier 1 comprises a first surface 11 and a second surface 12 which are oppositely arranged, and the first surface 11 and the second surface 12 are both flat surfaces.

S120A, forming a first bonding layer on the first surface and forming a second bonding layer on the second surface. In this step, as shown in FIGS. 2 to 3 (the first step), a bonding layer 2 is formed on both the first surface 11 and the second surface 12 of the supporting carrier 1, and the bonding layer 2 includes a first bonding layer 21 and a second bonding layer 22. The bonding layer 2 has a certain adhesion and can fix the semiconductor device 3 on the first surface 11 and/or the second surface 12 of the supporting carrier 1. The bonding layer 2 can be formed by taping or coating processes, Subsequently, the semiconductor device 3 can be separated from the supporting carrier 1 by thermal debonding, laser debonding or mechanical debonding.

It should be noted that the thickness of the first bonding layer 21 is equal to the thickness of the second bonding layer 22, or the difference between the thickness of the layer 21 and the thickness of the second bonding layer 22 is less than the preset threshold. which is not limited herein.

In some embodiments, “forming a first bonding layer on a first surface and a second bonding layer on a second surface” includes the steps of:

And forming a first bonding layer and a second bonding layer by adopting taping process.

In some embodiments, adhesive films (e.g., Dual-sided tape) are adhered to the first surface 11 and the second surface 12 of the supporting carrier 1, i.e., the first bonding layer 21 and the second bonding layer 22 are formed; the bonding surface is exposed by removing the backing paper, and the attachment of the semiconductor device 3 and the supporting carrier 1 can be completed by connecting the passive surface of the semiconductor device 3 with the bonding surface, which is easy to operate.

In some embodiments, forming a first bonding layer on a first surface of a supporting carrier and a second bonding layer on a second surface of the supporting carrier includes the steps of:
Forming the first bonding layer and the second bonding layer by adopting coating process;
Baking the first bonding layer and the second bonding layer.

In this embodiment, the raw material for preparing the first bonding layer 21 and the second bonding layer 22 is underfill epoxy, which is in a viscous fluid state and has certain fluidity. Firstly, coating underfill epoxy layers with a preset thickness on the first surface 11 and the second surface 12 of the supporting carrier 1, that is a first bonding layer 21 and a second bonding layer 22; and then the first bonding layer 21 and the second bonding layer 22 are baked to optimize the adhesion of the first bonding layer 21 and the second bonding layer 22, both to ensure that the semiconductor device 3 is not disconnected to the supporting carrier during the packaging process and to ensure that the semiconductor device 3 and the packaging material layer in connect to the supporting carrier 1 are not damaged when the supporting carrier 1 is subsequently removed.

And S130A, providing the semiconductor device, and attaching the passive surface of the semiconductor device to the one side surface of the first bonding layer, which faces away from the supporting carrier, and/or the one side surface of the second bonding layer, which faces away from the supporting carrier. Wherein, the semiconductor device 3 includes, but is not limited to, a die, a chip, and a wafer. The semiconductor device 3 includes a passive surface and an active surface that are disposed opposite to each other, and the active surface is provided with bonding sites and is electrically connected to the redistribution layer 5 prepared in the subsequent step S140A.

In this embodiment, the packaging method adopted by Face-up, the passive surface of the semiconductor device 3 faces the bonding layer 2, and the active surface of the semiconductor device 3 faces away from the bonding layer 2, that is the active surface of the semiconductor device 3 faces outside. The semiconductor device 3 can be attached only on the side surface of the first bonding layer 21 facing away from the supporting carrier 1, the semiconductor device 3 can also be attached only on the side surface of the second bonding layer 22 facing away from the supporting carrier 1, alternatively, the semiconductor device 3 can be attached to both the first bonding layer 21 and the second bonding layer 22 on the side surfaces facing away from the supporting carrier 1.

S140, forming a molding layer.

In this embodiment, the molding layer 4 wraps the semiconductor device 3 and exposes the active surface of the semiconductor device 3, and the molding layer 4 also covers the surface of the first bonding layer 21 and the second bonding layer 22 on the side facing away from the supporting carrier 1 that is not covered by the semiconductor device 3. The molding layer 4 can be made of materials such as Molding Compound (MC) or liquid or powder epoxy resin and other materials.

In other embodiments, the molding layer 4 can also be made of a half-cure material, which includes one or a combination of one or more of epoxy resin, polyethylene, polypropylene, polyolefin, polyamide, polyurethane, etc.

S150A, forming a redistribution layer on one side surface of the molding layer faces away from the first bonding layer, and one side surface of the molding layer faces away from the second bonding layer.

In some embodiments, the redistribution layer 5 comprises at least one patterned metal layer and at least one isolating layer, and is made of a metal material with good conductivity, including but not limited to copper, titanium, gold, silver, aluminum and tin; the redistribution layer 5 is electrically connected to the active surface of the semiconductor device 3.

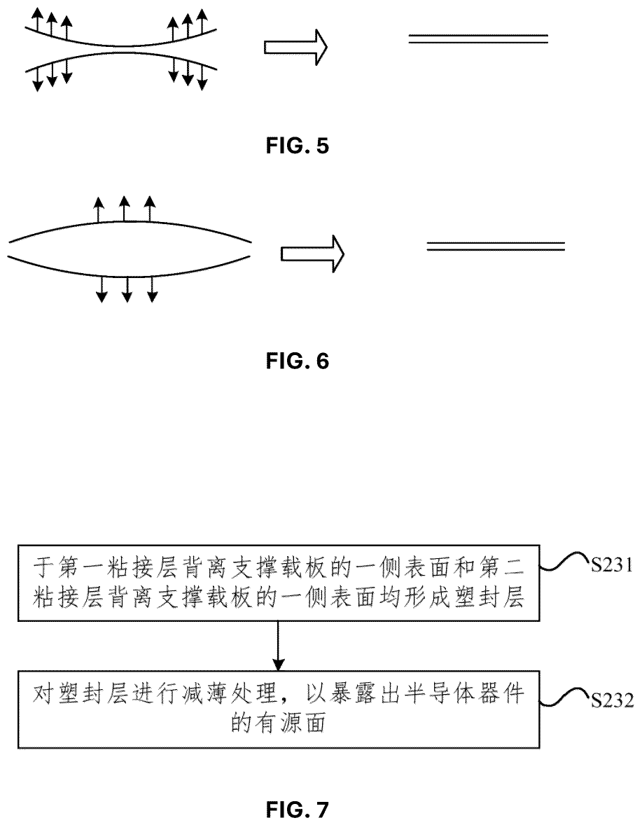

According to the different warpage directions, the type of warpage can be classified into “smiling face warpage” (as shown in FIG. 5) and “crying face warpage” (as shown in FIG. 6). As shown in FIG. 5, the “smiling face warpage” refers to the fact that stress generated by the packaging material layer is concentrated at the edge, the warpage degree of the edge area is larger than that of the middle area, and the surface of the wafer is an arc surface with the middle recessed downwards and the edge tilted upwards. As shown in FIG. 6, the “crying face warpage” means that the stress generated by the packaging material layer is concentrated in the middle area, and the warpage degree of the middle area is greater than that of the edge area, so that the surface of the wafer presents an arc surface with the middle rising upwards and the edge falling downwards. According to the embodiment of the disclosure, the Dual-sided packaging is performed on the upper surface and the lower surface opposite to each other of the supporting carrier, namely, the same packaging material layers are formed on the two sides of the supporting carrier, and due to the fact that the structures are symmetrical, stress generated by the packaging material layers is opposite in direction, and the stress is identical (under ideal conditions) or similar in size, the stress can be completely or partially offset, and therefore warpage is reduced.

It should be noted that during the packaging process, the semiconductor device 3 has very little impact on warpage, and therefore, the semiconductor device can be selectively attached to one side surface or both side surfaces of the supporting carrier 1 according to the need. The bonding layer 2, the molding layer 4 and the redistribution layer 5 are limited by the fabrication process and the materials used, the influence on the wafer warpage is very large, and the bonding layer, the molding layer 4 and the redistribution layer 5 are required to be arranged on the upper surface and the lower surface of the supporting carrier 1.

In some embodiments, as shown in FIG. 3, the upper and lower surfaces (the first surface 11 and the second surface 12) of the supporting carrier 1 are encapsulated at the same time, the first bonding layer 21 is formed on the first surface 11, the second bonding layer 22 is formed on the second surface 12, then the semiconductor device 3 is attached to the surfaces of the first bonding layer 21 and the second bonding layer 22 on the side facing away from the supporting carrier 1, and then the same packaging material layers (at least the molding layer 4 and the redistribution layer 5) are formed on two sides of the supporting carrier 1 in sequence, and the packaging material layers are symmetrically distributed along the plane of the supporting carrier, so that the directions of stresses are opposite, and the magnitudes of the stresses are equal or similar, and can offset each other, thereby reducing the warpage. Meanwhile, the semiconductor device 3 is attached to both the surface of the first bonding layer 21, which faces away from the supporting carrier 1, and the surface of the second bonding layer 22, which faces away from the supporting carrier1, which is beneficial to improve the packaging efficiency.

In some embodiments, as shown in FIG. 4, a bonding layer 2 (including a first bonding layer 21 and a second bonding layer 22) is formed on the first surface 11 and the second surface 12 of the supporting carrier 1, the semiconductor device 3 is attached on a side surface of the first bonding layer 21 facing away from the supporting carrier 1, and then, packaging is performed simultaneously on a side surface of the first bonding layer 21 facing away from the supporting carrier 1 and a side surface of the second bonding layer 22 facing away from the supporting carrier 1, and identical packaging material layers (including at least a molding layer and a redistribution layer) are formed on two sides of the supporting carrier 1 in sequence, and the packaging material layers are symmetrically distributed in a horizontal direction, and generate opposite stresses, which are equal or similar in size and offset each other, so that warpage can be reduced. In addition, the packaging material layer positioned on the side surface of the second bonding layer, to which the semiconductor device 3 is not attached, has reduced precision requirements and fabrication difficulty, and is also beneficial to improve packaging efficiency.

The fabrication method of the fan-out package provided by the embodiment of the disclosure comprises the following steps: providing a supporting carrier 1; wherein, the supporting carrier 1 comprises a first surface 11 and a second surface 12 which are oppositely arranged; forming a first bonding layer 21 on the first surface 11 and a second bonding layer 22 on the second surface 12; providing a semiconductor device 3 and attaching the passive face of the semiconductor device 3 to a side surface of the first bonding layer 21 facing away from the supporting carrier 1 and/or a side surface of the second bonding layer 22 facing away from the supporting carrier 1; forming a molding layer 4; the molding layer 4 wraps the semiconductor device 3 and exposes the active surface of the semiconductor device 3, and the molding layer 4 also covers the surface of the first bonding layer 21, which faces away from the supporting carrier 1, and the surface of the second bonding layer 22, which faces away from the supporting carrier 1 and is not covered by the semiconductor device 3; a redistribution layer 5 is formed on the surface of one side of the molding layer 4, which faces away from the first bonding layer 21, and the surface of one side of the molding layer 4, which faces away from the second bonding layer 22; the redistribution layer 5 is electrically connected to the active surface of the semiconductor device 3. Therefore, the same packaging material layers (comprising the bonding layer 2, the redistribution layer 4 and the redistribution layer 5) are formed on the upper surface and the lower surface of the supporting carrier 1 simultaneously in a Dual-sided packaging mode, the stress generated by the packaging material layers on the upper surface is opposite to the stress generated by the packaging material layers on the lower surface, the sizes of the stress and the stress are similar or equal, the stress and the stress are mutually offset, the warpage degree is reduced, even the warpage is eliminated, and further the packaging efficiency and the yield are improved.

In some embodiments, as shown in FIG. 7, “forming a molding layer” includes the steps of:

S231, forming a molding layer on the surface of one side of the first bonding layer, which is away from the supporting carrier, and the surface of one side of the second bonding layer, which is away from the supporting carrier.

In combination with the third step of FIG. 3-3, the formed molding layer 4 encapsulates the semiconductor device 3, and the active surface of the semiconductor device 3 is completely encapsulated by the molding layer; the molding layer 4 also covers the surface of the side of the first bonding layer 21 facing away from the supporting carrier 1 and the surface of the side of the second bonding layer 22 facing away from the supporting carrier 1 that is not covered by the semiconductor device 3.

S232, back grinding the molding layer to expose the active surface of the semiconductor device.

In combination with the fourth step of FIG. 3-3, the molding layer 4 can be back grinding by using a chemical mechanical polishing (Chemical Mechanical Polishing, CMP) and/or grinding process until the molding layer 4 exposes an active surface of semiconductor device 3.

In some embodiments, “forming a molding layer” includes the steps of:

Forming the molding layer by using a compression molding or a transfer molding process.

Wherein, the material of the molding layer can be one or a combination of more of packaging molding material (Molding Compound, MC), epoxy resin, polyethylene, polypropylene, polyolefin, polyamide, polyurethane and ceramic. The molding layer is prepared by adopting compression molding and transfer molding processes, the molding material is pressurized and heated, the molding material is plasticized and flows to fill the die cavity, the molding material is cured after undergoing a crosslinking reaction, and the temperature, the pressure and the time are strictly controlled in the process.

In other embodiments, the molding layer may also be prepared using all processes known to those skilled in the technologies, such as injection molding, transfer molding and compression molding, which are not limited here.

In some embodiments, “attaching the passive face of the semiconductor device to a side surface of the first bonding layer facing away from the supporting carrier and/or a side surface of the second bonding layer facing away from the supporting carrier” comprises the steps of:
Attaching the passive face of the semiconductor device to a side surface of the first bonding layer facing away from the supporting carrier and a side surface of the second bonding layer facing away from the supporting carrier;

In some embodiments, along the thickness direction of the molding layer, the projection of the semiconductor device attached to the first bonding layer overlaps with the projection of the semiconductor device attached to the second bonding layer.

In the present embodiment, as shown in FIG. 3, along the thickness direction of the supporting carrier 1, the projection of the semiconductor device 3 attached to the first bonding layer 21 overlaps with the projection of the semiconductor device 3 attached to the second bonding layer 22, i.e., the semiconductor devices 3 are symmetrically distributed on the upper and lower surfaces of the supporting carrier 1; therefore, the fan-out type packaging bodies formed on the upper side and the lower side of the supporting carrier 1 are identical and symmetrical in structure, the generated stresses are opposite in direction and equal in size, and the warpage can be eliminated after the stresses are mutually offset.

In other embodiments, the semiconductor device 3 may be attached to one side of the supporting carrier 1, and the stress balance device may be attached to the other side, where the semiconductor device 3 and the stress balance device are symmetrically distributed on the upper and lower surfaces of the supporting carrier; wherein the dimensions and materials of the stress balance device and the semiconductor device 3 are the same.

In some embodiments, the redistribution layer includes at least one metal layer and at least one isolating layer, where the metal layer and the isolating layer are in one-to-one correspondence; the step of forming a redistribution layer on both the side surface of the molding layer, which faces away from the first bonding layer, and the side surface of the molding layer, which faces away from the second bonding layer, comprises the following steps:

And forming a metal layer and an isolating layer alternately in sequence on one side surface of the molding layer, which is away from the first bonding layer, and one side surface of the molding layer, which is away from the second bonding layer, until all metal layers and all isolating layers of the redistribution layer are formed on one side surface of the molding layer, which is away from the first bonding layer, and all metal layers and all isolating layers of the redistribution layer are formed on one side surface of the molding layer, which is away from the second bonding layer.

In some embodiments, as shown in FIG. 3 or 3, two redistribution layers 5 are needed to be prepared on two sides of the supporting carrier 1, each redistribution layer 5 includes three patterned metal layers and three isolating layers, the metal layers are in one-to-one correspondence with the isolating layers, and each isolating layer wraps the corresponding metal layer and exposes the metal layer on one side facing away from the semiconductor device; the redistribution layer 5 above the supporting carrier 1 comprises a first metal layer M1, a second metal layer M2 and a third metal layer M3, wherein isolating layers are arranged on the surface of the M1 and among the M1, the M2 and the M3; the redistribution layer 5 below the supporting carrier 1 includes a fourth metal layer M4, a fifth metal layer M5, and a sixth metal layer M6, where isolating layers are disposed on the surface of M4 and between M4, M5, and M6. The fabrication method of the redistribution layer 5 specifically comprises the following steps: (1) Forming a first isolating layer of the redistribution layer 5 above the supporting carrier 1, forming a patterned via hole in the first isolating layer by adopting a photoetching or etching process, wherein the shape of the via hole is the shape of a first metal layer M1, forming the first metal layer M1 in the via hole by utilizing a sputtering or electroplating process, and repeating the steps to form a fourth isolating layer and a fourth metal layer M4 of the redistribution layer below the supporting carrier 1; (2) Then forming a second isolating layer and a second metal layer M2 on one side of the first metal layer M1, which is away from the plastic sealing layer 4, and forming a fifth isolating layer and a fifth metal layer M5 on one side of the fourth metal layer M4, which is away from the plastic sealing layer 4; (3) A third isolating layer and a third metal layer M3 are formed on one side of the second metal layer M2 facing away from the first metal layer M1, and a sixth isolating layer and a sixth metal layer M6 are formed on one side of the fifth metal layer M5 facing away from the fourth metal layer M4. When the redistribution layer 5 includes more metal layers, the above steps (2) or (3) are repeated until all the metal layers and all the isolating layers of the redistribution layer are formed.

It should be noted that, all processes known to those skilled in the technologies are used to prepare the patterned metal layer, such as photolithography+sputtering+electroplating processes, which are not described herein. FIGS. 3 and 3 show only an exemplary example in which the number of the redistribution layer 5 including the isolating layer and the metal layer is 3, but do not constitute a method of manufacturing the fan-out type package provided for the embodiment of the present disclosure. In other embodiments, the number of the redistribution layer 5 including the isolating layer and the metal layer may also be 1, 2, 4 or more, which is not limited herein.

In some embodiments, after forming the redistribution layer on both the side surface of the molding layer facing away from the first bonding layer and the side surface of the molding layer facing away from the second bonding layer, the method further includes the steps of:

Forming a connection structure on the surface of one side of the redistribution layer, which is away from the semiconductor device;

In some embodiments, connection structure is connected to the redistribution layer electricity, and connection structure is used for connecting external device.

In some embodiments, as shown in FIG. 3-3, the connection structure 6 includes solder balls electrically connected to the redistribution layer 5, the redistribution layer 5 being electrically connected to the active surface of the semiconductor device 3, such that electrical connection of the semiconductor device 3 to external devices is achieved.

It should be noted that FIGS. 3 and 3 only exemplarily illustrate that the connection structure 6 is provided in a spherical shape, but do not constitute a limitation of the manufacturing method of the fan-out type package provided in the embodiment of the present disclosure. In other embodiments, the connection structure may be provided in other forms, such as a pillar or a bump, which is not limited herein.

It should be noted that FIGS. 3 and 3 only show the fabrication sequence and the relative positional relationship of the respective package material layers in the fabrication process of the fan-out package by way of example, and do not limit the number of the connection structures 6 and the semiconductor devices 3 and the size configuration of the respective package material layers, and may be flexibly set according to requirements.

In some embodiments, the method of making further comprises:

And the method for removing the supporting carrier includes one of thermal debonding, laser debonding and mechanical debonding.

In some embodiments, the mode of removing the supporting carrier can be selected according to the type of the supporting carrier. For example, if the supporting carrier is a glass carrier or other light-transmitting carrier, the composite carrier may be removed by any one of thermal debonding, mechanical debonding and laser debonding; if the supporting carrier is a stainless steel carrier or other opaque carrier, a thermal debonding or mechanical debonding is used to remove the composite carrier.

In some embodiments, after removing the support carrier, the method of preparing the fan-out package further comprises:
Dicing (or segmenting) at least the first packaging layers to obtain fan-out packages;

In some embodiments, the saw process includes at least one of dicing saw, dicing blades, laser grooving, and plasma cutting. In connection with the last step of FIGS. 2 & 3, after removing of the supporting carrier 1, dicing (or segmenting) at least the first packaging layers to obtain fan-out packages, that is, the package of the semiconductor device 3 is completed.

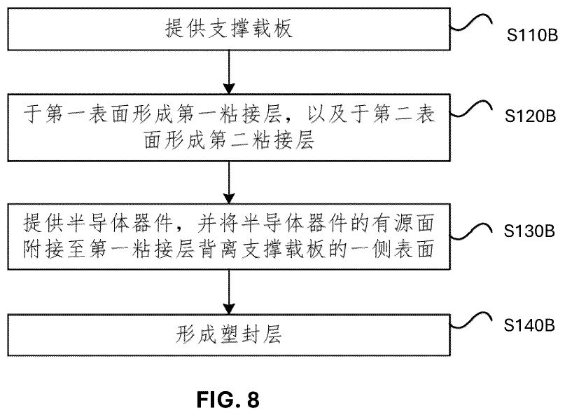

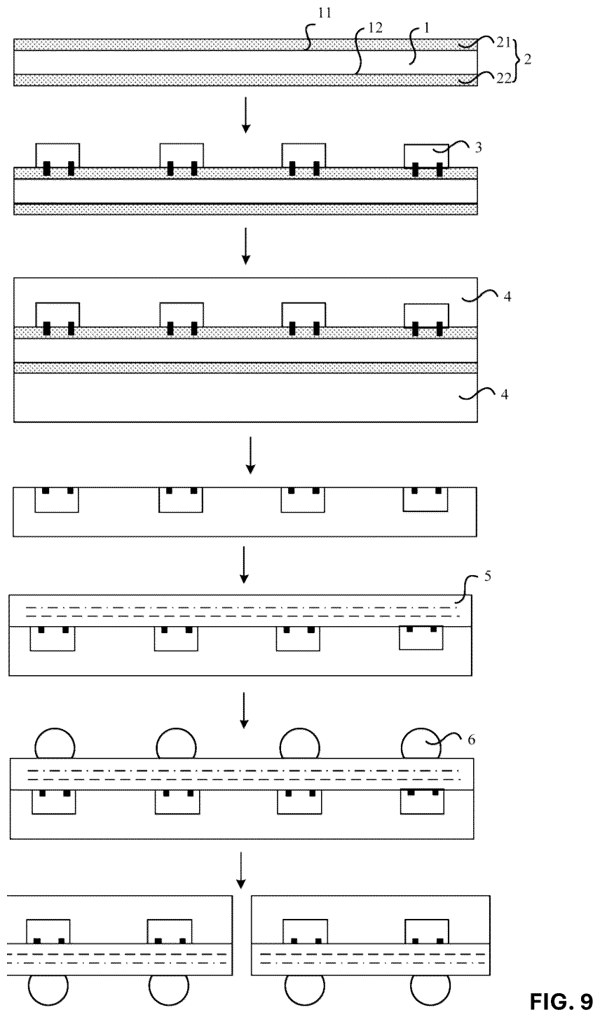

FIG. 8 is a schematic flow chart of an implementation 100B of the process 100 in the fabrication method for manufacturing a fan-out package provided by an embodiment of the present disclosure, FIG. 9 is a schematic diagram of various steps in a fabrication method for manufacturing a fan-out package provided by an embodiment of the present disclosure, Referring to FIGS. 8 & 9, the fabrication method includes the following steps:

S110B, providing a supporting carrier.

In some embodiments, the supporting carrier 1 is used for fixing and supporting the package; the supporting carrier 1 can be selected from all types of carriers known to those skilled in the technologies, such as a glass carrier or a stainless steel carrier and so on, which is not limited herein. The supporting carrier 1 comprises a first surface 11 and a second surface 12 which are oppositely arranged, and the first surface 11 and the second surface 12 are both flat surfaces.

S120B, forming a first bonding layer on the first surface and forming a second bonding layer on the second surface.

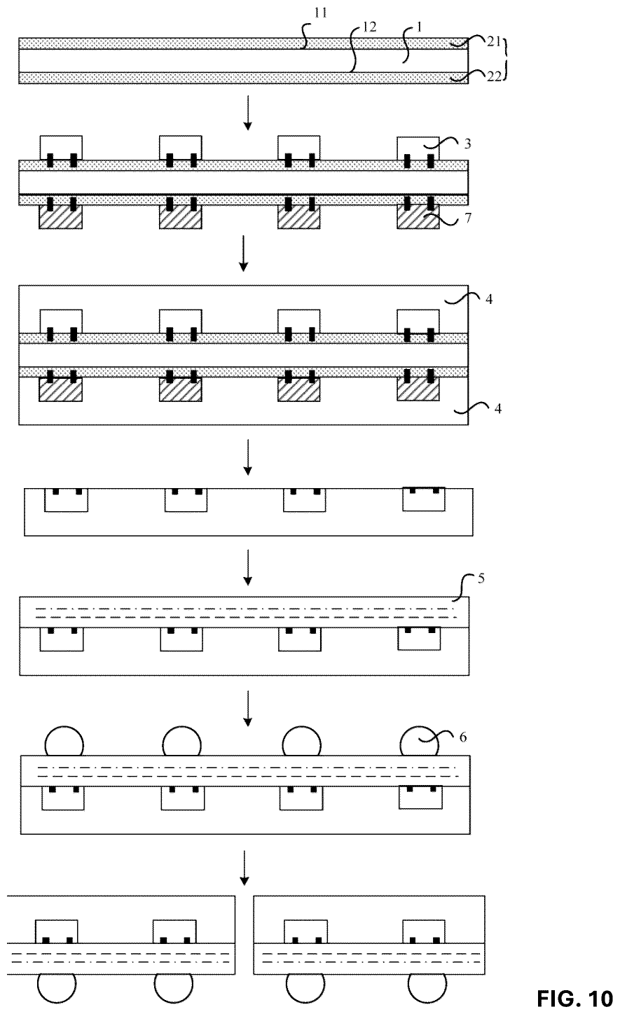

In this step, as shown in FIGS. 9 to 10 (the first step), a bonding layer 2 is formed on both the first surface 11 and the second surface 12 of the supporting carrier 1, and the bonding layer 2 includes a first bonding layer 21 and a second bonding layer 22. The bonding layer 2 has a certain adhesion and can fix the semiconductor device 3 on the first surface 11 and/or the second surface 12 of the supporting carrier 1. The bonding layer 2 can be formed by taping or coating processes, Subsequently, the semiconductor device 3 can be separated from the supporting carrier 1 by thermal debonding, laser debonding or mechanical debonding.

It should be noted that the thickness of the first bonding layer 21 is equal to the thickness of the second bonding layer 22, or the difference between the thickness of the layer 21 and the thickness of the second bonding layer 22 is less than the preset threshold. which is not limited herein.

In some embodiments, “forming a first bonding layer on a first surface and a second bonding layer on a second surface” includes the steps of:

And forming a first bonding layer and a second bonding layer by adopting a taping process.

In some embodiments, adhesive films (e.g., Dual-sided tape) are adhered to the first surface 11 and the second surface 12 of the supporting carrier 1, i.e., the first bonding layer 21 and the second bonding layer 22 are formed; the bonding surface is exposed by removing the backing paper, and the attachment of the semiconductor device 3 and the supporting carrier 1 can be completed by connecting the passive surface of the semiconductor device 3 with the bonding surface, which is easy to operate.

In some embodiments, forming a first bonding layer on a first surface of a supporting carrier and a second bonding layer on a second surface of the supporting carrier includes the steps of:
Forming the first bonding layer and the second bonding layer by adopting a coating process;
Curing the first bonding layer and the second bonding layer.

In this embodiment, the raw material for preparing the first bonding layer 21 and the second bonding layer 22 is underfill epoxy, which is in a viscous fluid state and has certain fluidity. Firstly, coating underfill epoxy layers with a preset thickness on the first surface 11 and the second surface 12 of the supporting carrier 1, that is a first bonding layer 21 and a second bonding layer 22; and then the first bonding layer 21 and the second bonding layer 22 are baked to optimize the adhesion of the first bonding layer 21 and the second bonding layer 22, both to ensure that the semiconductor device 3 is not disconnected to the supporting carrier during the packaging process and to ensure that the semiconductor device 3 and the packaging material layer in connect to the supporting carrier 1 are not damaged when the supporting carrier 1 is subsequently removed.

In the process of preparing the bonding layer 2, the bonding layer 2 needs to be baked or heated, the materials are heated to generate stresses, in order to balance the stresses, the bonding layer 2 is formed on the upper surface and the lower surface of the supporting carrier 1, the directions of the stresses generated by the first bonding layer 21 and the stress generated by the second bonding layer 22 are opposite, equal or similar, and the stresses can be offset each other, so that the warpage is reduced.

And S130B, providing the semiconductor devices, and attaching the active surface of the semiconductor devices to the surface of the side, facing away from the supporting carrier, of the first bonding layer.

In this embodiment, the semiconductor device 3 includes, but is not limited to, a die, a chip, and a wafer. The semiconductor device 3 includes a passive surface and an active surface that are disposed opposite to each other, and the active surface is provided with bonding sites and is electrically connected to the redistribution layer 5 prepared in the subsequent step.

In this embodiment, the packaging method adopted by Face-down, the active surface of the semiconductor device 3 faces the first bonding layer 21, and the passive surface of the semiconductor device 3 faces away from the first bonding layer 21, i.e. the active surface of the semiconductor device 3 faces the inner side. Illustratively, as shown in FIG. 9 or 3, the active face of the semiconductor component 3 is attached to a side surface of the first bonding layer 21 facing away from the supporting carrier 1. S140B, forming a molding layer.

In this embodiment, the molding layer 4 wraps the semiconductor device 3 and exposes the active surface of the semiconductor device 3, and the molding layer 4 also covers the surface of the first bonding layer 21 and the second bonding layer 22 on the side facing away from the supporting carrier 1 that is not covered by the semiconductor device 3. The molding layer 4 can be made of materials such as Molding Compound (MC) or liquid or powder epoxy resin and other materials.

In other embodiments, the molding layer 4 can also be made of a half-cure material, which includes one or a combination of one or more of epoxy resin, polyethylene, polypropylene, polyolefin, polyamide, polyurethane, etc.

According to the different warpage directions, the type of warpage can be classified into “smiling face warpage” (as shown in FIG. 5) and “crying face warpage” (as shown in FIG. 6). As shown in FIG. 5, the “smiling face warpage” refers to the fact that the stresses generated by the packaging material layer is concentrated at the edge, the warpage degree of the edge area is larger than that of the middle area, and the surface of the wafer is an arc surface with the middle grooved downwards and the edge tilted upwards. As shown in FIG. 6, the “crying face warpage” means that the stress generated by the packaging material layer is concentrated in the middle area, and the warpage degree of the middle area is greater than that of the edge area, so that the surface of the wafer presents an arc surface with the middle rising upwards and the edge falling downwards. In the embodiment of the disclosure, the opposite upper and lower surfaces (i.e., the first surface 11 and the second surface 12) of the supporting carrier 1 are subjected to Dual-sided packages, that is, the same packaging material layers (including the bonding layer 2 and the molding layer 4) are formed on two sides of the supporting carrier 1, and due to symmetrical structures, stresses generated by the packaging material layers are opposite in directions, and the stresses are identical (under ideal conditions) or similar, so that the stresses can be completely offset or partially offset, and therefore warpage is reduced.

It should be noted that during the packaging process, the semiconductor device 3 has very little impact on warpage, and therefore, the semiconductor devices can be selectively attached to one side surface or both side surfaces of the supporting carrier 1 according to the need. The bonding layer 2 and the molding layer 4 are limited by the fabrication process and the materials used, the influence on the wafer warpage is very large, and the bonding layer and the molding layer 4 are required to be arranged on the upper surface and the lower surface of the supporting carrier 1.

In some embodiments, as shown in FIG. 9, a first bonding layer 21 is formed on the first surface 11 of the supporting carrier, a second bonding layer 22 is formed on the second surface 12, an active surface of the semiconductor device 3 is attached to a side surface of the first bonding layer 21 facing away from the supporting carrier 1, and then the same molding layer 4 is formed on a side surface of the first bonding layer 21 facing away from the supporting carrier 1 and a side surface of the second bonding layer 22 facing away from the supporting carrier 1, the molding layer 4 is symmetrically distributed along the horizontal direction, and the directions of the stresses generation are opposite. Their magnitudes are equal or similar and can offset each other, thereby reducing warpage. In addition, the precision requirements and fabrication difficulty of the molding layer located on the side surface of the supporting carrier 1 are not attached to the semiconductor device 3 are reduced, which is beneficial to improve the packaging efficiency.

The fabrication method of the fan-out package provided by the disclosure comprises the following steps: providing a supporting carrier 1; wherein, the supporting carrier 1 comprises a first surface 11 and a second surface 12 which are oppositely arranged; forming a first bonding layer 21 on the first surface 11 and a second bonding layer 22 on the second surface 12; providing a semiconductor device 3 and attaching an active face of the semiconductor device 3 to a side surface of the first bonding layer 21 facing away from the supporting carrier 1; forming a molding layer 4; the molding layer 4 covers the semiconductor device 3, and also covers the surface of the side of the first bonding layer 21 facing away from the supporting carrier 1, which is not covered by the semiconductor device 3, and the surface of the side of the second bonding layer 22 facing away from the supporting carrier 1. Therefore, the bonding layer 2 and the molding layer 4 are formed on the upper surface and the lower surface of the supporting carrier 1 simultaneously in a Dual-sided packaging mode, the stresses generated by the bonding layer 2 and the molding layer 4 on the upper surface are opposite to the stresses generated by the bonding layer 2 and the molding layer 4 on the lower surface, the sizes of the stresses and the stresses are similar or equal, the stresses and the stresses offset each other, the warpage degree is reduced, even the warpage is eliminated, and the packaging efficiency and the yield are improved.

In some embodiments, after “attaching an active face of the semiconductor devices to the side surface of the first bonding layer facing away from the supporting carrier”, the method of preparing further comprises:
Attaching a stress balancing device to the surface of the side of the second bonding layer, which faces away from the supporting carrier;
In some embodiments, along the thickness direction of the supporting carrier plate, the projection of the semiconductor devices overlaps with the projection of the stresses balance device.

In the present embodiment, as shown in FIG. 10, the first bonding layer 21 is attached to the active surface of the semiconductor device 3, the second bonding layer 22 is attached to the stresses balance device 7, and the projection of the semiconductor device 3 overlaps with the projection of the stresses balance device 7 in the thickness direction of the supporting carrier 1, that is, the semiconductor device 3 and the stresses balance device 7 are symmetrically distributed on the upper and lower surfaces of the supporting carrier 1; the stresses balance device 7 is equal in size and material to the semiconductor device 3. Therefore, the fan-out package formed on the upper side and the lower side of the supporting carrier 1 are identical and symmetrical in structure, the generated stresses are opposite in direction and equal in size, and the warpage can be eliminated after the stresses are mutually offset.

It should be noted that, since the package which is including the stresses balance device is eventually discarded, the precision requirement and the fabrication difficulty are reduced, which is beneficial to improve the packaging efficiency.

In some embodiments, “forming a molding layer” includes the steps of:

Forming the molding layer by using a compression molding or a transfer molding process.

Wherein, the material of the molding layer can be one or a combination of more of packaging molding material (Molding Compound, MC), epoxy resin, polyethylene, polypropylene, polyolefin, polyamide, polyurethane and ceramic. The molding layer is prepared by adopting compression molding and transfer molding processes, the molding material is pressurized and heated, the molding material is plasticized and flows to fill the die cavity, the molding material is cured after undergoing a crosslinking reaction, and the temperature, the pressure and the time are strictly controlled in the process.

In other embodiments, the molding layer may also be prepared using all processes known to those skilled in the technologies, such as injection molding, transfer molding and compression molding, which are not limited here.

In some embodiments, the method of making further comprises:

Forming a groove on the surface of the side of the molding layer, which is away from the first bonding layer; the grooves are used for releasing stresses.

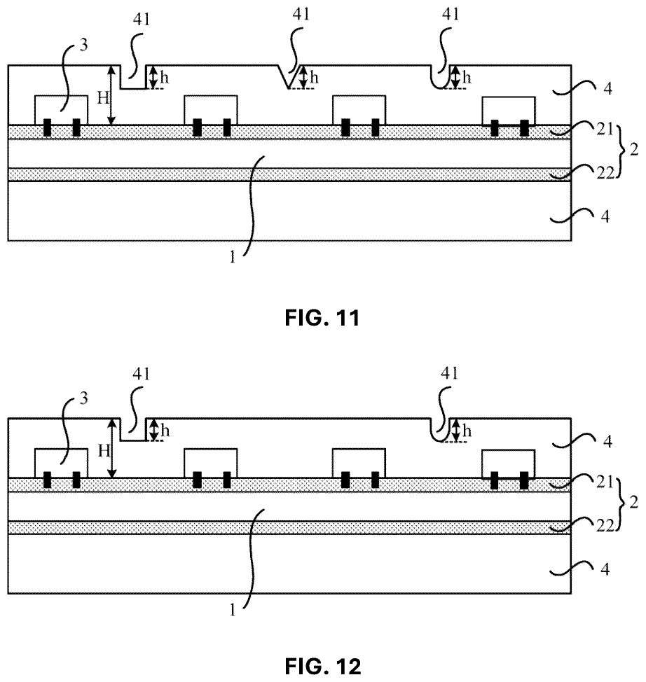

Referring to FIG. 11, the groove 41 is located on a side surface of the molding layer 4 facing away from the first bonding layer 21, so that when local stresses concentration occurs in the molding layer 4 due to uneven stresses or uneven expansion, the groove 41 can share the stresses which are originally too concentrated, thereby reducing and avoiding warpage caused by concentrated stresses.

In this embodiment, the groove 41 may be formed using one of in-mold ribs, mechanical saw, or etching processes. When the groove 41 is formed by adopting the mold inner rib process, the inner rib is required to be arranged at the corresponding position in the mold for preparing the molding layer 4, so that the molding layer 4 and the groove 41 are simultaneously formed by one process, thereby being beneficial to save the process and improve the packaging efficiency. When the groove is formed by a mechanical saw or etching process, it is necessary to form the groove 41 at a corresponding position of the molding layer by using a saw device or an etching device after forming the molding layer 4, and thus, the surface of the formed groove 41 is smooth and has high accuracy.

It should be noted that FIG. 11 only exemplarily illustrates that the number of grooves is 3, and the shape of the grooves may be rectangular, triangular or semicircular, but does not limit the method for manufacturing the fan-out package provided in the embodiment of the present disclosure. In other embodiments, the number and shape of the grooves can be flexibly set according to the requirements, and the grooves are not limited herein.

In some embodiments, forming a groove in a surface of a side of the molding layer facing away from the first bonding layer includes the steps of:

Forming a groove on the surface of the side of the molding layer between two adjacent semiconductor devices, which faces away from the first bonding layer.

In some embodiments, the projection of the groove 41 is located between the projections of the adjacent two semiconductor devices 3 in the thickness direction of the molding layer 4. Illustratively, as shown in FIG. 11, the groove 41 is located on a side surface of the molding layer 4 facing away from the first bonding layer 21 and is embedded between the adjacent two semiconductor devices 3. In this way, damage to the semiconductor device 3 during the process of opening the groove 41 is avoided.

It should be noted that FIG. 11 only exemplarily illustrates that one groove 41 is provided between every two adjacent semiconductor devices 3, but does not limit the fabrication method of the fan-out type package provided in the embodiment of the present disclosure. In other embodiments, a groove may be provided for a predetermined number of semiconductor devices 3 at intervals, which is not limited herein. For example, as shown in FIG. 12, a groove 41 is provided every 2 semiconductor devices 3.

In some embodiments, forming a groove in a side surface of the molding layer between two adjacent semiconductor devices facing away from the first bonding layer includes the steps of:

Along the thickness direction of the molding layer, the depth of the groove is less than or equal to ½ thickness of the molding layer.

In this embodiment, as shown in FIGS. 11 & 12, the depth of the groove 41 is smaller than the thickness of the molding layer 4, so that the groove 41 does not penetrate the molding layer 4, and the supporting carrier 1 or the bonding layer 2 below the molding layer 4 is not exposed, thereby ensuring the tightness of the molding layer 4. Further, the depth of the groove 41 is less than or equal to ½ of the thickness of the molding layer 4 (i.e., ½H), i.e. h≤½H.

It should be noted that, the embodiment of the present disclosure only exemplarily illustrates that the depth of the groove 41 is less than or equal to the preset depth, and the preset depth is ½ of the thickness of the molding layer 4 (i.e., ½H), but the method for manufacturing the fan-out package provided by the embodiment of the present disclosure is not limited. In other embodiments, the preset depth may be greater than ½H, or less than ½H, or a specific value, which is not limited herein.

In some embodiments, after “forming the molding layer,” the method of making further comprises:

Removing the supporting carrier by using one of thermal debonding, laser debonding and mechanical debonding to expose the active surface of the semiconductor devices.

In some embodiments, the mode of removing the supporting carrier can be selected according to the type of the supporting carrier. For example, if the supporting carrier is a glass carrier or other light-transmitting carrier, the composite carrier may be removed by any one of thermal debonding, mechanical debonding and laser debonding; if the supporting carrier is a stainless steel carrier or other opaque carrier, a thermal debonding or mechanical debonding is used to remove the composite carrier. After the supporting carrier 1 and the bonding layer 2 are removed in this step, the surface of the side where the molding layer 4 is originally attached to the bonding layer 2 is exposed, and the surface also exposes the active surface of the semiconductor device 3.

In some embodiments, the method of making further comprises:

Forming an interconnection structure on the surface of the side of the molding layer, which is exposed out of the active surface; the interconnection structure is electrically connected to the active surface and is used for connecting an external device.

The interconnection structure at least comprises a redistribution layer 5, In some embodiments, the redistribution layer 5 comprises at least one patterned metal layer and at least one insulator layer, and metal materials with good conductivity are selected from copper, titanium, gold, silver, aluminum and tin; the redistribution layer 5 is electrically connected to the active surface of the semiconductor device 3.

In some embodiments, as shown in FIG. 9 or 10, after removing the supporting carrier 1 and the bonding layer 2, a redistribution layer 5 is formed on a surface of the molding layer 4 on a side where the active surface of the semiconductor device 3 is exposed, and then a solder ball 6 is formed on a side of the redistribution layer 5 facing away from the semiconductor device 3, and the redistribution layer 5 is electrically connected to the semiconductor device 3 and the solder ball, so that electrical interconnection of the semiconductor device 3 to an external device is achieved.

It should be noted that FIGS. 9 and 10 only exemplarily illustrate that the interconnection structure connected to the external device is provided as the solder ball 6, but do not constitute a limitation of the manufacturing method of the fan-out type package provided in the embodiment of the present disclosure. In other embodiments, the interconnection structure connected to the external device may be provided in other forms, such as a pillar or a bump, which is not limited herein.

In some embodiments, the method of making further comprises:

dicing (or segmenting) at least the first packaging layers to obtain fan-out packages;

In some embodiments, the saw process includes at least one of dicing saw, dicing blades, laser grooving, and plasma cutting. In connection to the last step of FIG. 9 or 5, after removing the supporting carrier 1, the fan-out package is diced, i.e., the package of the semiconductor device 3 is completed.

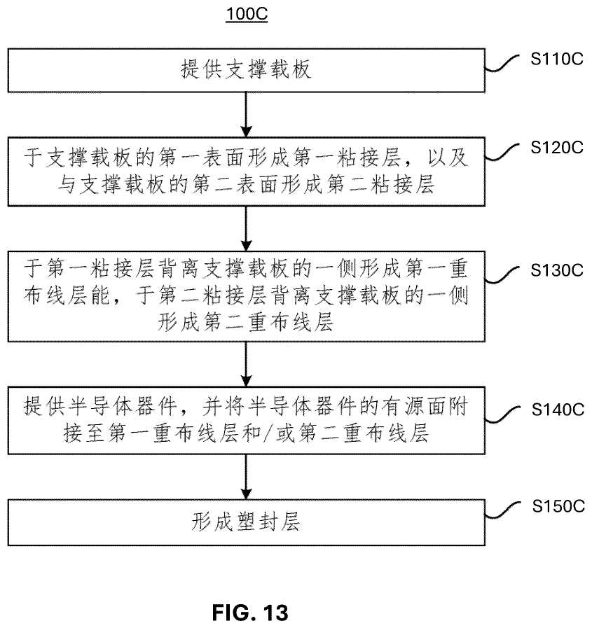

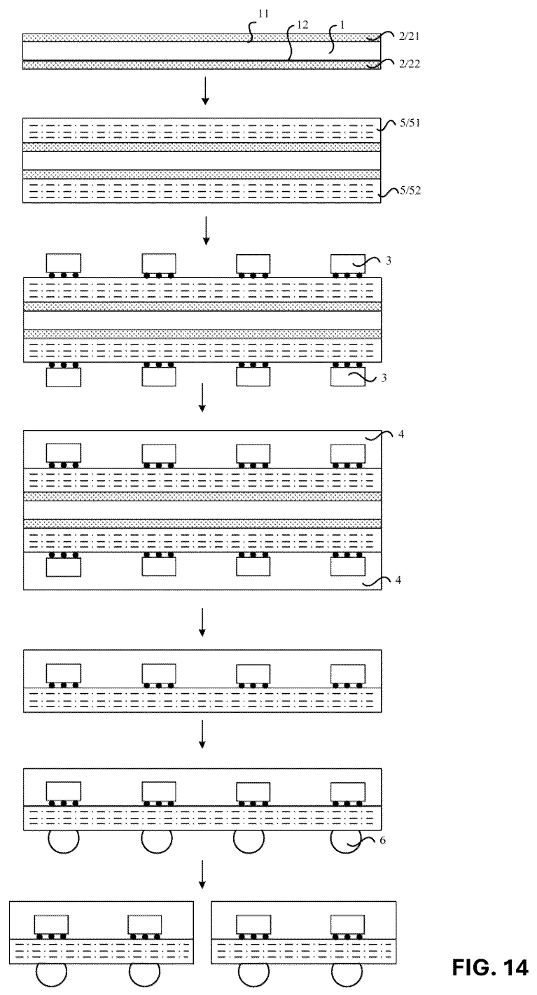

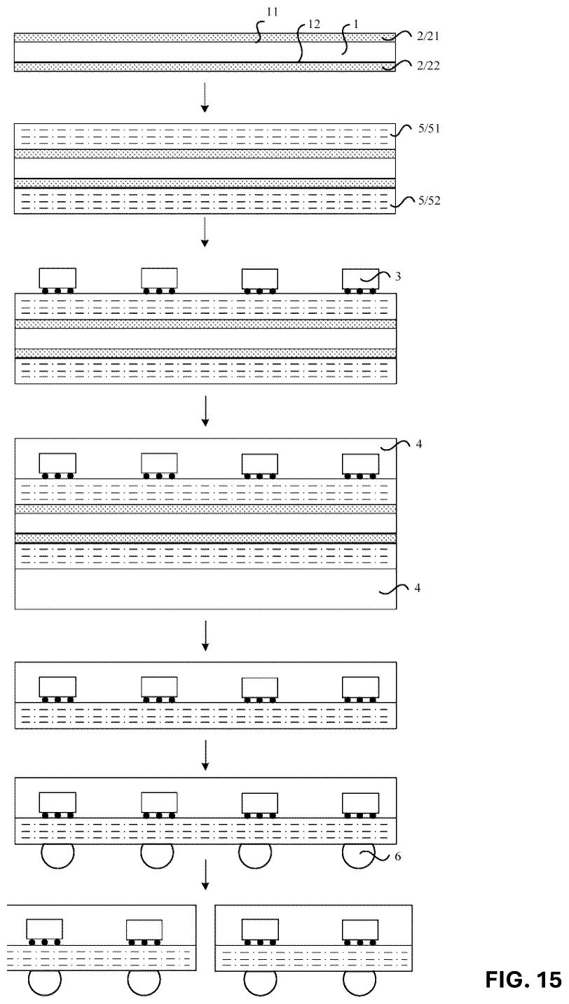

FIG. 13 is a schematic flow chart of an implementation 100C of the process 100 in the fabrication method for manufacturing a fan-out package provided by an embodiment of the present disclosure, FIG. 14 is a schematic diagram of various steps in a fabrication method for manufacturing a fan-out package provided by an embodiment of the present disclosure, FIG. 15 is a schematic diagram of various steps in another method for manufacturing a fan-out package provided by an embodiment of the present disclosure. Referring to FIGS. 1-3, the fabrication method includes the following steps:

S110C, providing a supporting carrier.

In some embodiments, the supporting carrier 1 is used for fixing and supporting the package; the supporting carrier 1 can be selected from all types of carriers known to those skilled in the technologies, such as a glass carrier or a stainless steel carrier and so on, which is not limited herein. The supporting carrier 1 comprises a first surface 11 and a second surface 12 which are oppositely arranged, and the first surface 11 and the second surface 12 are both flat surfaces.

S120C, forming a first bonding layer on the first surface of the supporting carrier and forming a second bonding layer on the second surface of the supporting carrier.

In this step, as shown in FIGS. 14 to 15 (the first step), a bonding layer 2 is formed on both the first surface 11 and the second surface 12 of the supporting carrier 1, and the bonding layer 2 includes a first bonding layer 21 and a second bonding layer 22. The bonding layer 2 has a certain adhesion and can fix the semiconductor device 3 on the first surface 11 and/or the second surface 12 of the supporting carrier 1. The bonding layer 2 can be formed by taping or coating processes, Subsequently, the semiconductor device 3 can be separated from the supporting carrier 1 by thermal debonding, laser debonding or mechanical debonding.

It should be noted that the thickness of the first bonding layer 21 is equal to the thickness of the second bonding layer 22, or the difference between the thickness of the layer 21 and the thickness of the second bonding layer 22 is less than the preset threshold. which is not limited herein.

In some embodiments, “forming a first bonding layer on a first surface and a second bonding layer on a second surface” includes the steps of:

And forming a first bonding layer and a second bonding layer by adopting a taping process.

In some embodiments, adhesive films (e.g., Dual-sided tape) are adhered to the first surface 11 and the second surface 12 of the supporting carrier 1, i.e., the first bonding layer 21 and the second bonding layer 22 are formed; the bonding surface is exposed by removing the backing paper, and the attachment of the semiconductor device 3 and the supporting carrier 1 can be completed by connecting the passive surface of the semiconductor device 3 with the bonding surface, which is easy to operate.

In some embodiments, forming a first bonding layer on a first surface of a supporting carrier and a second bonding layer on a second surface of the supporting carrier includes the steps of:
Forming the first bonding layer and the second bonding layer by adopting a coating process;
Curing the first bonding layer and the second bonding layer.

In this embodiment, the raw material for preparing the first bonding layer 21 and the second bonding layer 22 is underfill epoxy, which is in a viscous fluid state and has certain fluidity. Firstly, coating underfill epoxy layers with a preset thickness on the first surface 11 and the second surface 12 of the supporting carrier 1, that is a first bonding layer 21 and a second bonding layer 22; and then the first bonding layer 21 and the second bonding layer 22 are baked to optimize the adhesion of the first bonding layer 21 and the second bonding layer 22, both to ensure that the semiconductor device 3 is not disconnected to the supporting carrier during the packaging process and to ensure that the semiconductor device 3 and the packaging material layer in connect to the supporting carrier 1 are not damaged when the supporting carrier 1 is subsequently removed.

In the process of preparing the bonding layer 2, the bonding layer 2 needs to be baked or heated, the materials are heated to generate stress, in order to balance the stress, the bonding layer 2 is formed on the upper surface and the lower surface of the supporting carrier 1, the directions of the stress generated by the first bonding layer 21 and the stress generated by the second bonding layer 22 are opposite, equal or similar, and the stress can be offset each other, so that the warpage is reduced.

S130C, forming a first redistribution layer on one side of the first bonding layer, which is away from the supporting carrier, and forming a second redistribution layer on one side of the second bonding layer, which is away from the supporting carrier.

A first redistribution layer 51 and a second redistribution layer 52 each include at least one patterned metal layer and at least one insulator layer, and are made of a metal material with good conductivity, including but not limited to copper, titanium, gold, silver, aluminum, tin, and the like. The thickness of the first and second redistribution layers 51 and 52 are equal, or the difference in thickness between them is less than a preset threshold.

S140C, providing semiconductor devices, and attaching an active surface of the semiconductor devices to the first and/or second redistribution layers.

In this embodiment, a semiconductor device 3 includes, but is not limited to, a die, a chip, and a wafer. The semiconductor devices 3 includes a passive face and an active face that are disposed opposite to each other, the active face being provided with bonding sites. The active surface of the semiconductor devices 3 is attached to the first and/or second redistribution layers 51 and 52 by thermocompression bonding (Thermal Compress Bonding, TCB), Die Attach (DA), or Surface Mount (Surface Mount Technology, SMT), thereby achieving electrical interconnection of the semiconductor devices 3 to the first and/or second redistribution layers 51 and 52. The semiconductor devices 3 may be attached only to the first redistribution layer 51, the semiconductor devices 3 may also be attached only to the second redistribution layer 52, or the semiconductor devices 3 may be attached to both the first redistribution layer 51 and the second redistribution layer 52.

S150C, forming a molding layer.

In this embodiment, a molding layer 4 embeds the semiconductor devices 3 and also covers a surface of the first redistribution layer 51 facing away from the first bonding layer 21 and a surface of the second redistribution layer 52 facing away from the second bonding layer 22, which is not covered by the semiconductor devices 3. The thickness of the molding layer 4 on the first redistribution layer 51 is equal to the thickness of the molding layer 4 on the second redistribution layer 52, or the difference between the two thicknesses is smaller than a preset threshold.

In other embodiments, the molding layer 4 can also be made of a half-cure material, which includes one or a combination of one or more of epoxy resin, polyethylene, polypropylene, polyolefin, polyamide, polyurethane, etc.

In other embodiments, the packaging method adopted by RDL-first, and the bonding layer 2 and the redistribution layer 5 are formed on both sides of the support carrier, that is, the first bonding layer 21 and the first redistribution layer 51 are sequentially formed on the first surface 11 of the support carrier 1, the second bonding layer 22 and the second redistribution layer 52 are sequentially formed on the second surface 12, then the semiconductor devices 3 is fixed, and then the molding layer 4 is formed on both the redistribution layers 5.

According to the different warpage directions, the type of warpage can be classified into “smiling face warpage” (as shown in FIG. 5) and “crying face warpage” (as shown in FIG. 6). As shown in FIG. 5, the “smiling face warpage” refers to the fact that stress generated by the packaging material layer is concentrated at the edge, the warpage degree of the edge area is larger than that of the middle area, and the surface of the wafer is an arc surface with the middle recessed downwards and the edge tilted upwards. As shown in FIG. 6, the “crying face warpage” means that the stress generated by the packaging material layer is concentrated in the middle area, and the warpage degree of the middle area is greater than that of the edge area, so that the surface of the wafer presents an arc surface with the middle rising upwards and the edge falling downwards. According to the embodiment of the disclosure, the Dual-sided packaging is performed on the upper surface and the lower surface opposite to each other of the supporting carrier, namely, the same packaging material layers are formed on the two sides of the supporting carrier, and due to the fact that the structures are symmetrical, stress generated by the packaging material layers is opposite in direction, and the stress is identical (under ideal conditions) or similar in size, the stress can be completely or partially offset, and therefore warpage is reduced.

It should be noted that during the packaging process, the semiconductor device 3 has very little impact on warpage, and therefore, the semiconductor device can be selectively attached to one side surface or both side surfaces of the supporting carrier 1 according to the need. The bonding layer 2, the molding layer 4 and the redistribution layer 5 are limited by the fabrication process and the materials used, the influence on the wafer warpage is very large, and the bonding layer 2, the molding layer 4 and the redistribution layer 5 are required to be arranged on the upper surface and the lower surface of the supporting carrier 1.

In some embodiments, As shown in FIG. 14, the package is performed on the upper and lower surfaces (the first surface 11 and the second surface 12) of the support carrier 1, the first bonding layer 21 is formed on the first surface 11 of the support carrier 1, the second bonding layer 22 is formed on the second surface, the first redistribution layer 51 is formed on the side of the first bonding layer 21 facing away from the support carrier 1, the second redistribution layer 52 is formed on the side of the second bonding layer 22 facing away from the support carrier 1, the semiconductor devices 3 is attached to both the first redistribution layer 51 and the second redistribution layer 52, the molding layer 4 is formed on the outer side of the redistribution layer 5, and the package material layers (including the bonding layer 2, the redistribution layer 5 and the molding layer 4) are symmetrically distributed along the horizontal direction, and the directions of the stresses generated are opposite, equal or similar, and can cancel each other, so that warpage can be reduced. Meanwhile, the semiconductor devices 3 is attached on both the first and second redistribution layers 51 and 52, which is advantageous in improving packaging efficiency.

In some embodiments, As shown in FIG. 15, the upper and lower surfaces of the supporting carrier 1 are encapsulated at the same time, and the difference from FIG. 14 is that: the semiconductor devices 3 is attached only on the first redistribution layer 51, and the same packaging material layer (including the bonding layer 2, the molding layer 4 and the redistribution layer 5) is formed on two surfaces of the support carrier 1 opposite to each other, and the packaging material layers are symmetrically distributed along the horizontal direction, and the directions of stresses generated are opposite, equal or similar, and can offset each other, so that the warpage can be reduced. In addition, the semiconductor devices 3 is not attached to the second redistribution layer 52, and the package formed on this side is eventually discarded, so that the accuracy requirement and the manufacturing difficulty thereof are reduced, and the improvement of the packaging efficiency is facilitated.

The fabrication method of the fan-out package provided by the embodiment of the disclosure comprises the following steps: providing a supporting carrier 1; wherein, the supporting carrier 1 comprises a first surface 11 and a second surface 12 which are oppositely arranged; forming a first bonding layer 21 on the first surface 11 and a second bonding layer 22 on the second surface 12; forming a first redistribution layer 51 on a side of the first bonding layer 21 facing away from the support carrier 1, and forming a second redistribution layer 52 on a side of the second bonding layer 22 facing away from the support carrier 1; providing a semiconductor devices 3 and attaching an active face of the semiconductor devices 3 to the first and/or second redistribution layers 51, 52; forming a molding layer 4; the molding layer 4 covers the semiconductor devices 3 and also covers the surface of the first redistribution layer 51 that is not covered by the semiconductor devices 3, of the side surface facing away from the first bonding layer 21 and the side surface of the second redistribution layer 52 that is facing away from the second bonding layer 22. Therefore, the same packaging material layers (comprising the bonding layer 2, the redistribution layer 5 and the molding layer 4) are formed on the upper surface and the lower surface of the supporting carrier 1 simultaneously in a Dual-sided packaging mode, and the stresses generated by the packaging material layers on the upper surface and the stresses generated by the packaging material layers on the lower surface are opposite in direction and similar or equal in size, and offset with each other, so that the warpage degree is reduced, even the warpage is eliminated, and the packaging efficiency and the yield are improved.

In some embodiments, a first redistribution layer includes at least one metal layer and at least one insulator layer; a second redistribution layer comprises at least one metal layer and at least one insulator layer; forming the first redistribution layer on a side of the first bonding layer facing away from the supporting carrier, and forming the second redistribution layer on a side of the second bonding layer facing away from the supporting carrier, including:

Forming a metal layer and an insulator layer alternately in sequence on one side of the first bonding layer, which is away from the supporting carrier, and one side of the second bonding layer, which is away from the supporting carrier, until all metal layers and all insulator layers of the first redistribution layer are formed on one side of the first bonding layer, which is away from the supporting carrier, and all metal layers and insulator layers of the second redistribution layer are formed on one side of the second bonding layer, which is away from the supporting carrier.

In some embodiments, As shown in FIG. 14 or 3, it is necessary to prepare a redistribution layer 5 on each of the first bonding layer 21 and the second bonding layer 22 on the side facing away from the supporting carrier 1, each redistribution layer 5 including three patterned metal layers and three insulator layers, the metal layers being in one-to-one correspondence with the insulator layers, each insulator layer embedding the corresponding metal layer and exposing the metal layer on the side facing away from the semiconductor devices; the first redistribution layer 51 includes a first metal layer M1, a second metal layer M2, and a third metal layer M3, where insulator layers are disposed on the surface of M1 and among M1, M2, and M3; the second redistribution layer 52 includes a fourth metal layer M4, a fifth metal layer M5, and a sixth metal layer M6, and insulator layers are provided on the surfaces of the M4 and between the M4, M5, and M6. The fabrication method of the redistribution layer 5 specifically comprises the following steps: (1) Forming a first insulator layer of the first redistribution layer 51, forming a patterned Through Silicon Via in the first insulator layer by adopting a photoetching or etching process, wherein the shape of the Through Silicon Via is the shape of a first metal layer M1, forming the first metal layer M1 in the Through Silicon Via by utilizing a sputtering or electroplating process, and repeating the steps to form a fourth insulator layer and a fourth metal layer M4 of the second redistribution layer 52; (2) Then forming a second insulator layer and a second metal layer M2 on one side of the first metal layer M1, which is away from the molding layer 4, and forming a fifth insulator layer and a fifth metal layer M5 on one side of the fourth metal layer M4, which is away from the molding layer 4; (3) A third insulator layer and a third metal layer M3 are formed on one side of the second metal layer M2 facing away from the first metal layer M1, and a sixth insulator layer and a sixth metal layer M6 are formed on one side of the fifth metal layer M5 facing away from the fourth metal layer M4. When the redistribution layer 5 includes more metal layers, the above-described step (2) or (3) is repeated until all metal layers and all insulator layers of the first redistribution layer 51 and all metal layers and all insulator layers of the second redistribution layer 52 are formed.

It should be noted that, all processes known to those skilled in the technologies are used to prepare the patterned metal layer, such as photolithography+sputtering+electroplating processes, which are not described herein. FIGS. 14 and 15 show only an exemplary example in which the number of the redistribution layer 5 including the insulator layer and the metal layer is 3, but do not constitute a method for fabricating fan-out package provided for the embodiment of the present disclosure. In other embodiments, the number of the redistribution layer 5 including the insulator layer and the metal layer may also be 1, 2, 4 or more, which is not limited herein.

In some embodiments, “attaching an active face of the semiconductor devices to the first and/or second redistribution layers” includes:
Attaching an active face of the semiconductor devices to a side surface of the first redistribution layer facing away from the first bonding layer and a side surface of the second redistribution layer facing away from the second bonding layer;
In some embodiments, in the thickness direction of the support carrier 1, the projection of the semiconductor devices 3 attached to the first redistribution layer 51 overlaps with the projection of the semiconductor devices 3 attached to the second redistribution layer 52.

In the present embodiment, as shown in FIG. 14, along the thickness direction of the support carrier 1, the projections of the semiconductor devices 3 attached to the first redistribution layer 51 overlap with the projections of the semiconductor devices 3 attached to the second redistribution layer 52, i.e., the semiconductor devices 3 are symmetrically distributed on the upper and lower surfaces of the support carrier 1; therefore, the fan-out package formed on the upper side and the lower side of the supporting carrier 1 are identical and symmetrical in structure, the generated stresses are opposite in direction and equal in size, and the warpage can be eliminated after the stresses are mutually offset.

In some embodiments, “attaching an active face of the semiconductor devices to the first and/or second redistribution layer” includes the steps of:
Attaching an active surface of the semiconductor devices to a surface of the first redistribution layer facing away from the first bonding layer;
Attaching a stress balancing device to a surface of the second redistribution layer on a side thereof facing away from the second bonding layer;
In some embodiment, along the thickness direction of the supporting carrier 1, the projection of the semiconductor devices 3 overlaps with the projection of the stress balance device 7.

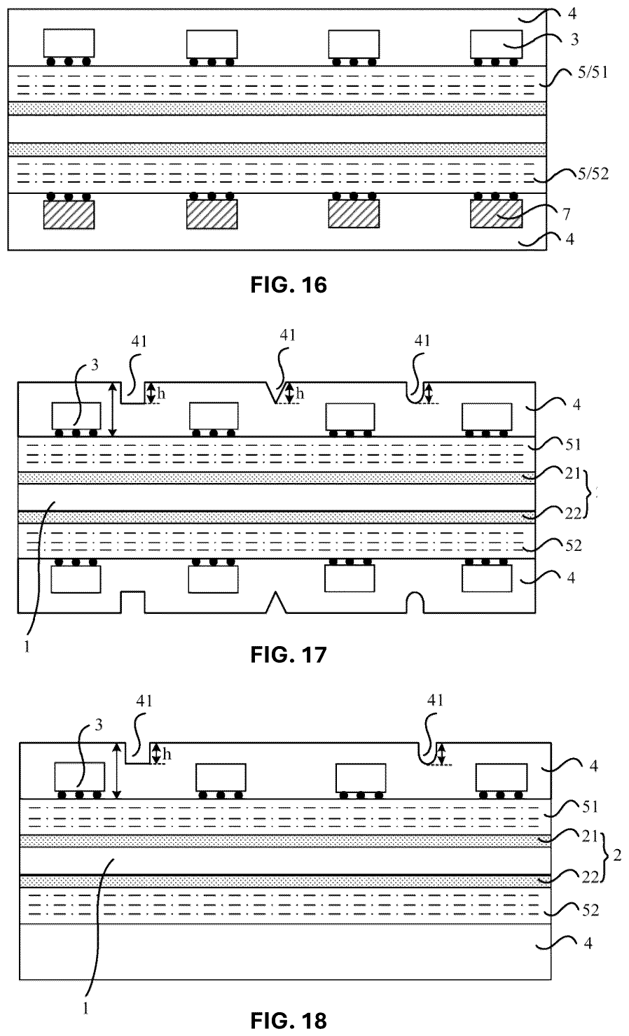

In this embodiment, as shown in FIG. 16, the semiconductor devices 3 is attached to a side surface of the first redistribution layer 51 facing away from the first bonding layer 21, the stress balance device 7 is attached to a side surface of the second redistribution layer 52 facing away from the second bonding layer 22, and the projection of the semiconductor devices 3 overlaps with the projection of the stress balance device 7 in the thickness direction of the support carrier 1, that is, the semiconductor devices 3 and the stresses balance device 7 are symmetrically distributed on the upper and lower surfaces of the support carrier 1; the stresses balance device 7 is equal in size and material to the semiconductor devices 3. Therefore, the fan-out package formed on the upper side and the lower side of the supporting carrier 1 are identical and symmetrical in structure, the generated stresses are opposite in direction and equal in size, and the warpage can be eliminated after the stresses are mutually offset.

In some embodiments, “forming a molding layer” includes the steps of:

Forming a molding layer by adopting a compression molding or transfer molding process.

Wherein, the material of the molding layer can be one or a combination of more of packaging molding material (Molding Compound, MC), epoxy resin, polyethylene, polypropylene, polyolefin, polyamide, polyurethane and ceramic. The molding layer is prepared by adopting compression molding and transfer molding processes, the molding material is pressurized and heated, the molding material is plasticized and flows to fill the die cavity, the molding material is cured after undergoing a crosslinking reaction, and the temperature, the pressure and the time are strictly controlled in the process.

In other embodiments, the molding layer may also be prepared using all processes known to those skilled in the technologies, such as injection molding, transfer molding and compression molding, which are not limited here.

In some embodiments, the method of making further comprises:

Forming a groove on the surface of one side of the molding layer, which is away from the supporting carrier; the grooves are used for releasing stresses.

Referring to FIG. 17, the groove 41 is located on a side surface of the molding layer 4 away from the supporting carrier 1 (i.e. a side surface of the molding layer 4 away from the first redistribution layer 51 and a side surface of the molding layer 4 away from the second redistribution layer 52), so that when local stresses concentration occurs to the molding layer 4 due to uneven stresses or uneven expansion, the groove 41 can share the originally excessively concentrated stresses, thereby reducing and avoiding warpage caused by the concentrated stresses.

In this embodiment, the groove 41 may be formed using one of in-mold ribs, mechanical saw, or etching processes. When the groove 41 is formed by adopting the mold inner rib process, the inner rib is required to be arranged at the corresponding position in the mold for preparing the molding layer 4, so that the molding layer 4 and the groove 41 are simultaneously formed by one process, thereby being beneficial to save the process and improve the packaging efficiency. When the groove is formed by a mechanical saw or etching process, it is necessary to form the groove 41 at a corresponding position of the molding layer by using a saw device or an etching device after forming the molding layer 4, and thus, the surface of the formed groove 41 is smooth and has high accuracy.

It should be noted that FIG. 17 only exemplarily illustrates that the number of grooves is 3, and the shape of the grooves may be rectangular, triangular or semicircular, but does not limit the method for manufacturing the fan-out package provided in the embodiment of the present disclosure. In other embodiments, the number and shape of the grooves can be flexibly set according to the requirements, and the grooves are not limited herein.

In some embodiments, forming a groove in a surface of a side of the molding layer facing away from the supporting carrier includes:

Forming a groove on the surface of one side of the molding layer between two adjacent semiconductor devices, which faces away from the supporting carrier.

In some embodiments, the projection of the groove 41 is located between the projections of the adjacent two semiconductor devices 3 in the thickness direction of the molding layer 4. Illustratively, as shown in FIG. 17, the groove 41 is located on a side surface of the molding layer 4 facing away from the support carrier 1 and is interposed between two adjacent semiconductor devices 3. In this way, damage to the semiconductor devices 3 during the opening of the groove 41 is avoided.

It should be noted that FIG. 17 only exemplarily illustrates that one groove 41 is provided between every two adjacent semiconductor devices 3, but does not limit the fabrication method of fan-out package provided in the embodiment of the present disclosure. In other embodiments, a groove may be provided for a predetermined number of semiconductor devices 3 at intervals, which is not limited herein. For example, as shown in FIG. 18, one groove 41 is provided every 2 semiconductor devices 3.

In some embodiments, forming a groove in a surface of a side of the molding layer between two adjacent semiconductor devices facing away from the support carrier includes:

Along the thickness direction of the molding layer, the depth of the groove is less than or equal to ½ thickness of the molding layer.

In this embodiment, as shown in FIGS. 17 & 18, the depth of the groove 41 is smaller than the thickness of the molding layer 4, so that the groove 41 does not penetrate the molding layer 4, and the supporting carrier 1 and the bonding layer 2 below the molding layer 4 are not exposed, thereby ensuring the tightness of the molding layer 4. Further, the depth of the groove 41 is less than or equal to ½ of the thickness of the molding layer 4 (i.e., ½H), i.e., h=½H.

It should be noted that, the embodiment of the present disclosure only exemplarily shows that the depth of the groove 41 is less than or equal to the preset depth, and the preset depth is ½ of the thickness of the molding layer 4 (i.e., ½H), but the embodiment of the present disclosure does not limit the fan-out package. In other embodiments, the preset depth may be greater than ½H, or less than ½H, or a specific value, which is not limited herein.

In some embodiments, after “forming the molding layer,” the method of making further comprises:

Removing the supporting carrier and the bonding layer by adopting one of thermal debonding, laser debonding and mechanical debonding.

The mode of removing the supporting carrier can be selected according to the type of the supporting carrier. For example, if the supporting carrier is a glass carrier or other light-transmitting carrier, the composite carrier may be removed by any one of thermal debonding, laser debonding and mechanical debonding; if the supporting carrier is a stainless steel carrier or other opaque carrier, a thermal debonding or mechanical debonding is used to remove the composite carrier. After the supporting carrier 1 and the bonding layer 2 are removed in this step, the surface of the side where the redistribution layer 5 is originally attached to the bonding layer 2 is exposed.

In some embodiments, the method of making further comprises:
Forming an interconnection structure on the surface of one side of the redistribution layer, which is away from the semiconductor devices;
In some embodiments, the interconnection structure 6 is electrically connected to the redistribution layer 5, the interconnection structure being for connecting an external device.

In some embodiments, as shown in FIGS. 14 & 15, the interconnection structure 6 includes solder balls electrically connected to the redistribution layer 5, the redistribution layer 5 being electrically connected to the active surface of the semiconductor devices 3, such that electrical interconnection of the semiconductor devices 3 to external devices is achieved.

It should be noted that FIGS. 14 and 15 only exemplarily illustrate that the interconnection structure 6 is provided in a spherical shape, but do not constitute a limitation of the fabrication method of fan-out package provided in the embodiment of the present disclosure. In other embodiments, the interconnection structure may be provided in other forms, such as a pillar or a bump, which is not limited herein.

It should be noted that FIGS. 14 and 3 only show the fabrication sequence and the relative positional relationship of the respective packaging material layers in the fabrication process of the fan-out package by way of example, and do not limit the number of the connection structures 6 and the semiconductor devices 3 and the size configuration of the respective packaging material layers, and may be flexibly set according to requirements.

In some embodiments, the method of making further comprises:
dicing the packaging layers to obtain the fan-out package;
In some embodiments, the saw process includes at least one of dicing saw, dicing blades, laser grooving, and plasma cutting.

It is noted that relational terms such as “bottom” and “top” and the like are used solely to distinguish one entity or action from another entity or action without necessarily requiring or implying any actual such relationship or order between such entities or actions. Moreover, the terms “comprises,” “comprising,” or any other variation thereof, are intended to cover a non-exclusive inclusion, such that a process, method, material, or equipment that comprises a list of elements does not include only those elements but may include other elements not expressly listed or inherent to such process, method, material, or equipment. Without further limitation, an element defined by the phrase “comprising one” does not exclude the presence of other like elements in a process, method, material, or equipment that comprises the element.

The foregoing is merely a specific embodiment of the disclosure to enable one skilled in the technologies to understand or practice the disclosure. Various modifications to these embodiments will be readily apparent to those skilled in the technologies, and the generic principles defined herein may be applied to other embodiments without departing from the spirit or scope of the disclosure. Thus, the present disclosure is not intended to be limited to the embodiments shown and described herein but is to be accorded the widest scope includeent with the principles and novel features disclosed herein.

1. A method of fabricating fan-out package, comprising:
forming packaging layers on opposite sides of a supporting carrier, the packaging layers including one or more first packaging layers on a first side of the supporting carrier and one or more second package layers on a second side of the supporting carrier, the second side being opposite to the first side, the one or more first packaging layers including a first molded package layer, the one or more second packaging layers including a second molded package layer, at least the first molded package layer embedding one or more semiconductor devices; and
separating at least the one or more first packaging layers from the carrier board.

2. The method of claim 1, wherein stress generated by forming the first molded package layer is about equal in magnitude as stress generated by forming the second molded package layer.

3. The method of claim 1, wherein the second molded package layer is about equal in thickness as the first molded package layer.

4. The method of claim 1, wherein forming packaging layers on opposite sides of the supporting carrier comprises:
forming the first bonding layer on the first side and forming the second bonding layer on the second side;
providing a semiconductor device, and attaching the passive face of the semiconductor device to one side surface of the first bonding layer facing away from the supporting carrier and/or one side surface of the second bonding layer facing away from the supporting carrier;
forming a molding layer; the molding layer wraps the semiconductor device and exposes the active surface of the semiconductor device, and the molding layer also covers one side surface of the first bonding layer facing away from the supporting carrier, and one side surface of the second bonding layer facing away from the supporting carrier, which is not covered by the semiconductor device; and
forming a redistribution layer on a surface on one side of the molding layer facing away from the first bonding layer, and one side surface of the molding layer facing away from the second bonding layer; the redistribution layer is electrically connected to the active surface of the semiconductor device.

5. The method of claim 4, wherein forming a first bonding layer on the first side and a second bonding layer on the second side comprises:
forming the first bonding layer and the second bonding layer using a taping process or a coating process; and
curing the first bonding layer and the second bonding layer.

6. The method of claim 4, wherein forming the molding layer comprises:
forming the molding layer on a surface on one side of the first bonding layer facing away from the supporting carrier, and a surface on one side of the second bonding layer facing away from the supporting carrier; wherein, the molding layer covers the semiconductor device, and the molding layer also covers a surface of the first bonding layer facing away from the supporting carrier and a surface of the second bonding layer facing away from the supporting carrier. The side surface is not covered by the semiconductor device; and
polishing the molding layer to expose the active surface of the semiconductor device.

7. The method of claim 4, wherein forming the molding layer comprise forming the molding layer using a compression molding or a transfer molding process.

8. The method of claim 4, wherein attaching the passive surface of the semiconductor device to one side surface of the first bonding layer facing away from the supporting carrier and/or one side surface of the second bonding layer facing away from the supporting carrier comprises:
attaching a passive surface of the semiconductor device to one side surface of the first bonding layer facing away from the supporting carrier and one side surface of the second bonding layer facing away from the supporting carrier;
wherein, along the thickness direction of the molding layer, the projection of the semiconductor device attached to the first bonding layer overlaps with the projection of the semiconductor device attached to the second bonding layer.

9. The method of claim 4, wherein the mentioned redistribution layer includes at least one metal layer and at least one isolating layer, the metal layer corresponds to the isolating layer one by one; the redistribution layer is formed on one side surface of the molding layer facing away from the first bonding layer and one side surface of the molding layer facing away from the second bonding layer, and wherein:
one side surface of the molding layer facing away from the first bonding layer, and one side surface of the molding layer facing away from the second bonding layer, are sequentially and alternately formed into one metal layer and one isolating layer, until one side surface of the molding layer facing away from the first bonding layer is formed into all metal layers and all isolating layers of the redistribution layer, and one side surface of the molding layer facing away from the second bonding layer is formed into all metal layers and all isolating layers of the redistribution layer.

10. The method according to any one of claim 4, after forming a redistribution layer on both a side surface of the molding layer facing away from the first bonding layer and a side surface of the molding layer facing away from the second bonding layer, the method further comprises:
forming a connection structure on one side surface of the redistribution layer, which is away from the semiconductor device; the connection structure is electrically connected to the redistribution layer and is used for connecting an external device.

11. The method of claim 10, further comprising:
removing the supporting carrier using thermal debonding, laser debonding or mechanical debonding.

12. The method of claim 11, further comprising, after removing the supporting carrier:
dicing the first packaging layers to obtain fan-out packages using at least one of dicing saw, dicing blades, laser grooving, and plasma cutting.

13. The method of claim 1, wherein forming packaging layers on opposite sides of the supporting carrier comprises:
forming a first bonding layer on the first side and forming a second bonding layer on the second side;
providing semiconductor devices, and attaching an active face of the semiconductor devices to a surface of the first bonding layer, which faces away from the supporting carrier; and
forming a molding layer; the molding layer embeds the semiconductor devices and also covers one side surface of the first bonding layer facing away from the supporting carrier, and one side surface of the second bonding layer facing away from the supporting carrier, which is not covered by the semiconductor device;

14. The method of claim 13, wherein, after attaching the active face of the semiconductor devices to the side surface of the first bonding layer facing away from the supporting carrier, the method further comprises:
attaching stress balancing devices to the surface of one side of the second bonding layer away from the supporting carrier; and the projection of the semiconductor devices is overlapped with the projection of the stresses balance device along the thickness direction of the supporting carrier.

15. The method of claim 13, further comprising:
forming grooves on in a surface of one side of the molding layer, which is away from the first bonding layer, to release stress.

16. The method of claim 15, wherein forming grooves in the surface of the molding layer facing away from the first bonding layer comprises:
forming each grooves between two adjacent semiconductor devices.

17. The method of claim 16, wherein along the thickness direction of the molding layer, the depth of each groove is smaller than or equal to ½ of the thickness of the molding layer.

18. The method of claim 1, wherein forming packaging layers on opposite sides of the supporting carrier comprises:
providing a supporting carrier; the supporting carrier comprises a first side and a second side which are oppositely arranged;
forming a first bonding layer on the first side of the supporting carrier and forming a second bonding layer on the second side of the supporting carrier;
forming a first redistribution layer on one side of the first bonding layer, which is away from the supporting carrier, and forming a second redistribution layer on one side of the second bonding layer, which is away from the supporting carrier;
providing semiconductor devices and attaching an active face of the semiconductor devices to the first and/or second redistribution layers; and
forming a molding layer; the molding layer embeds the semiconductor devices and also covers one side surface of the first bonding layer facing away from the supporting carrier, and one side surface of the second bonding layer facing away from the supporting carrier, which is not covered by the semiconductor device.

19. The method of claim 18, wherein the first redistribution layer comprises at least one metal layer and at least one insulator layer; the second redistribution layer comprises at least one metal layer and at least one insulator layer; the first redistribution layer is formed on one side of the first bonding layer which is away from the supporting carrier, and the second redistribution layer is formed on one side of the second bonding layer, which is away from the supporting carrier, and wherein forming the redistribution layer comprises:
one side of the first bonding layer, which is away from the supporting carrier, and one side of the second bonding layer, which is away from the supporting carrier, alternately forming one metal layer and one insulator layer in sequence until one side of the first bonding layer, which is away from the supporting carrier, forming all metal layers and all insulator layers of the first redistribution layer, and one side of the second bonding layer, which is away from the supporting carrier, forming all metal layers and all insulator layers of the second redistribution layer.

20. The fabrication method of claim 18, wherein attaching active faces of the semiconductor devices to the first and/or second redistribution layer comprises:
attaching an active face of a first semiconductor device to a side surface of the first redistribution layer facing away from the first bonding layer and a stress balancing device or an active face of a second semiconductor device to a side surface of the second redistribution layer facing away from the second bonding layer;
wherein, along the thickness direction of the support carrier, the projection of the first semiconductor device attached to the first redistribution layer overlaps with the projection of the stress balancing device or the second semiconductor device attached to the second redistribution layer.
